(19) United States
(12) Patent Application Publication
(10) Pub. No.: US 2025/0120273 A1
(43) Pub. Date: Apr. 10, 2025

(54) DISPLAY DEVICE

(71) Applicant: Samsung Display Co., Ltd., Yongin-Si (KR)

(72) Inventor: JONGHYUN CHOI, Yongin-si (KR)

(21) Appl. No.: 18/904,110

(22) Filed: Oct. 2, 2024

(30) Foreign Application Priority Data
Oct. 10, 2023 (KR) 10-2023-0134690

(51) Int. Cl. H10K 59/131; H10K 59/95

(52) U.S. Cl. CPC H10K 59/131; H10K 59/95

(57) ABSTRACT

A display device includes pixel circuit groups disposed in a matrix form along a first direction and a second direction intersecting the first direction in the display area, each pixel circuit group including pixel circuits, a first driver disposed in the non-display area, positioned on one side of the display area, and providing a data voltage to the pixel circuits, a second driver disposed in the non-display area, positioned on the other side opposite to the one side of the display area, and providing a driving signal to the pixel circuits, a first connection line connected to the second driver and extending in the first direction, a second connection line connected to the first connection line in a separation space between adjacent pixel circuit groups and extending in the second direction, and a signal line connected to the second connection line and transmitting the driving signal to the pixel circuits.

### CROSS-REFERENCE TO RELATED APPLICATION

This application claims priority under 35 USC § 119 to Korean Patent Application No. 10-2023-0134690, filed on Oct. 10, 2023, in the Korean Intellectual Property Office, the content of which is herein incorporated by reference in its entirety.

### BACKGROUND

### 1. Field

The present disclosure relates generally to a display device. More particularly, the present disclosure relates to a display device that provides visual information.

### 2. Description of the Related Art

With the development of information technology, the importance of a display device, which is a connection medium between a user and information, has been highlighted. For example, the use of display devices such as liquid crystal display (LCD) device, organic light emitting display (OLED) device, plasma display panel (PDP) device, quantum dot display device or the like is increasing.

The display device may include a display area that displays an image and a non-display area that does not display an image. In order to expand the display area in the display device, research is being conducted to reduce an area occupied by the non-display area.

### SUMMARY

Embodiments provide a display device with a relatively small non-display area and suppressed display defect.

A display device according to an embodiment of the present disclosure includes a substrate including a display area and a non-display area surrounding the display area, pixel circuit groups disposed in a matrix form along a first direction and a second direction, which intersects the first direction, on the substrate in the display area, each of the pixel circuit groups including pixel circuits, a first driver disposed on the substrate in the non-display area on one side of the display area, and providing a data voltage to the pixel circuits, a second driver disposed on the substrate in the non-display area on the other side which is opposite to the one side of the display area, and providing a driving signal to the pixel circuits, a first connection line connected to the second driver and extending in the first direction, a second connection line connected to the first connection line in a separation space between adjacent pixel circuit groups and extending in the second direction, and a signal line connected to the second connection line and transmitting the driving signal provided from the second driver to the pixel circuits.

In an embodiment, the second connection line and the signal line may be connected in the non-display area at a first contact point. The first connection line and the second connection line may be connected in the display area at a second contact point.

In an embodiment, the second driver may be positioned to be spaced apart from the display area in the first direction, and the first contact point may be positioned to be spaced apart from the display area in the second direction.

In an embodiment, the second contact point may be positioned in a first separation space between the adjacent pixel circuit groups arranged along the first direction.

In an embodiment, the display device may further include a light emitting element positioned in the separation space between the adjacent pixel circuit groups. At least a portion of the second connection line may overlap the light emitting element in a plan view.

In an embodiment, the second contact point may be positioned in a second separation space between the adjacent pixel circuit groups arranged along the second direction.

In an embodiment, the second driver may include a gate driver which provides a gate signal to the pixel circuits. The first connection line may include a first gate connection line connected to the gate driver. The second connection line may include a second gate connection line connected to the first gate connection line. The signal line may include a gate signal line which is connected to the second gate connection line and transmits the gate signal provided from the gate driver.

In an embodiment, the second driver may include an emission driver which provides an emission control signal to the pixel circuits. The first connection line may include a first emission connection line connected to the emission driver. The second connection line may include a second emission connection line connected to the first emission connection line. The signal line may include an emission signal line which is connected to the second emission connection line and transmits the emission control signal provided from the emission driver.

In an embodiment, the display device may further include a constant voltage line providing a constant voltage to the pixel circuits. The constant voltage line may include a first constant voltage line connected to the second driver and extending in the first direction, and a second constant voltage line connected to the first constant voltage line and extending in the second direction. The first constant voltage line and the second constant voltage line may be connected in the display area at a third contact point.

In an embodiment, the third contact point may overlap each of the pixel circuits in a plan view.

In an embodiment, the third contact point may be positioned in the separation space between the adjacent pixel circuit groups.

In an embodiment, the non-display area may include a first driver area positioned on the one side of the display area and where the first driver is disposed, a second driver area positioned on the other side of the display area and where the second driver is disposed, and bending areas respectively positioned between the display area and the first driver area and between the display area and the second driver area in a plan view. The substrate may be bendable about a reference axis parallel to the second direction in the bending areas.

In an embodiment, the second connection line may include at least one selected from a group consisting of aluminum, copper, silver, molybdenum, and titanium.

A display device according to another embodiment of the present disclosure includes a substrate including a display area and a non-display area surrounding the display area, pixel circuit groups disposed in a matrix form along a first direction and a second direction, which intersects the first direction, on the substrate in the display area, each of the pixel circuit groups including pixel circuits, a first driver disposed on the substrate in the non-display area on one side of the display area, and providing a data voltage to the pixel circuits, a second driver disposed on the substrate in the non-display area on the one side of the display area, and providing a driving signal to the pixel circuits, a first connection line connected to the second driver and extending in the first direction, a second connection line connected to the first connection line in a separation space between adjacent pixel circuit groups and extending in the second direction, and a signal line connected to the second connection line and transmitting the driving signal provided from the second driver to the pixel circuits.

In an embodiment, the second connection line and the signal line may be connected in the non-display area at a first contact point. The second driver may be positioned to be spaced apart from the display area in the first direction, and the first contact point may be positioned to be spaced apart from the display area in the second direction.

In an embodiment, the first connection line and the second connection line may be connected in the display area at a second contact point. The second contact point may be positioned in a first separation space between the adjacent pixel circuit groups arranged along the first direction.

In an embodiment, the first connection line and the second connection line may be connected in the display area at a second contact point. The second contact point may be positioned in a second separation space between the adjacent pixel circuit groups arranged along the second direction.

In an embodiment, the second driver may include a gate driver which provides a gate signal to the pixel circuits. The first connection line may include a first gate connection line connected to the gate driver. The second connection line may include a second gate connection line connected to the first connection line. The signal line may include a gate signal line which is connected to the second gate connection line and transmits the gate signal provided from the gate driver.

In an embodiment, the second driver may include an emission driver which provides an emission control signal to the pixel circuits. The first connection line may include a first emission connection line connected to the emission driver. The second connection line may include a second emission connection line connected to the first emission connection line. The signal line may include an emission signal line which is connected to the second emission connection line and transmits the emission control signal provided from the emission driver.

In an embodiment, the non-display area may include a driver area positioned on the one side of the display area and where each of the first driver and the second driver is disposed, and a bending area positioned between the display area and the driver area in a plan view. The substrate may be bendable about a reference axis parallel to the second direction in the bending area.

A display device according to an embodiment of the present disclosure may include a substrate including a display area and a non-display area surrounding the display area, pixel circuit groups disposed on the substrate in the display area, each of the pixel circuit groups including pixel circuits, a second driver disposed on the substrate in the non-display area, positioned to be spaced apart from the display area in a first direction, and providing a driving signal to the pixel circuits, a first connection line connected to the second driver and extending in the first direction, a second connection line connected to the first connection line and extending in a second direction which intersects the first direction and a signal line connected to the second connection line and transmitting the driving signal to the pixel circuits.

As the substrate is bent, the second driver may be positioned on a lower surface of the display device. Accordingly, compared to a case where the second driver is positioned in the second direction from the display area, the dead space of the display device may be reduced.

The second connection line may be connected to the first connection line in a separation space between adjacent pixel circuit groups at a second contact point. In addition, the signal line may be connected to the second connection line in the non-display area at a first contact point. That is, each of the first contact point and the second contact point may be spaced apart from the pixel circuits in a plan view. Accordingly, the display defects in which spots are visible in the display device may be suppressed.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to a first embodiment of the present disclosure.

FIG. 2 is a side view illustrating a bent shape of the display device of FIG. 1.

FIG. 3 is an enlarged plan view of area ‘A’ of FIG. 1.

FIG. 4 is a cross-sectional view illustrating the display device of FIG. 1.

FIG. 5 is a block diagram illustrating the display device of FIG. 1.

FIG. 6 is a circuit diagram illustrating a pixel included in the display device of FIG. 1.

FIGS. 7, 8, 9, and 10 are plan views illustrating the display device of FIG. 1.

FIG. 11 is a plan view illustrating a display device according to a second embodiment of the present disclosure.

FIG. 12 is a plan view illustrating a display device according to a third embodiment of the present disclosure.

FIG. 13 is a plan view illustrating a display device according to a fourth embodiment of the present disclosure.

FIG. 14 is a plan view illustrating a display device according to a fifth embodiment of the present disclosure.

FIG. 15 is a plan view illustrating a display device according to a sixth embodiment of the present disclosure.

FIG. 16 is a side view illustrating a bent shape of the display device of FIG. 15.

FIGS. 17 and 18 are plan views illustrating the display device of FIG. 15.

FIG. 19 is a plan view illustrating a display device according to a seventh embodiment of the present disclosure.

FIG. 20 is a plan view illustrating a display device according to an eighth embodiment of the present disclosure.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions of the same components will be omitted.

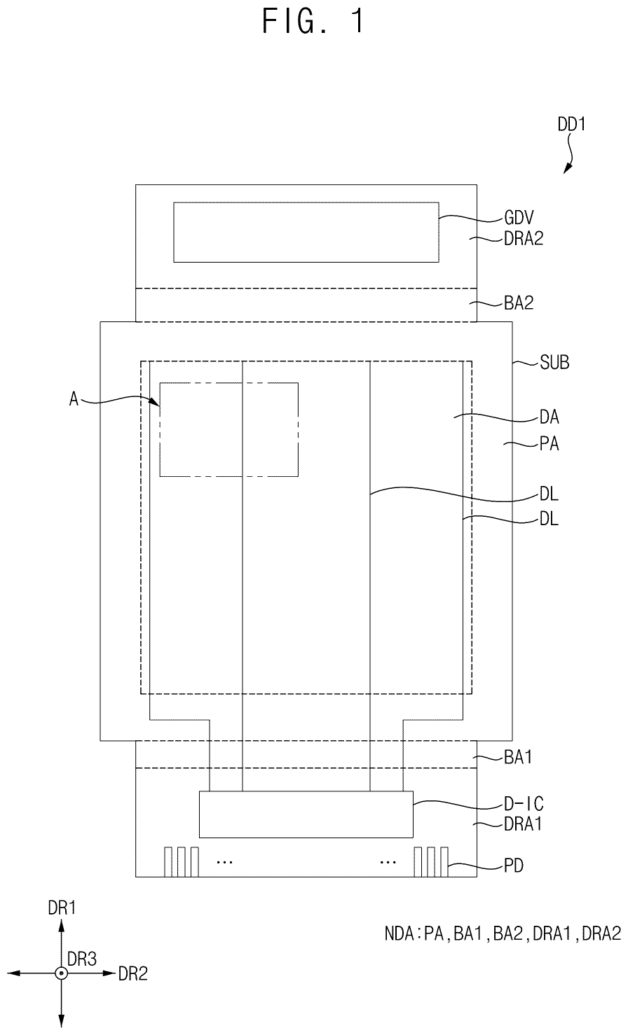

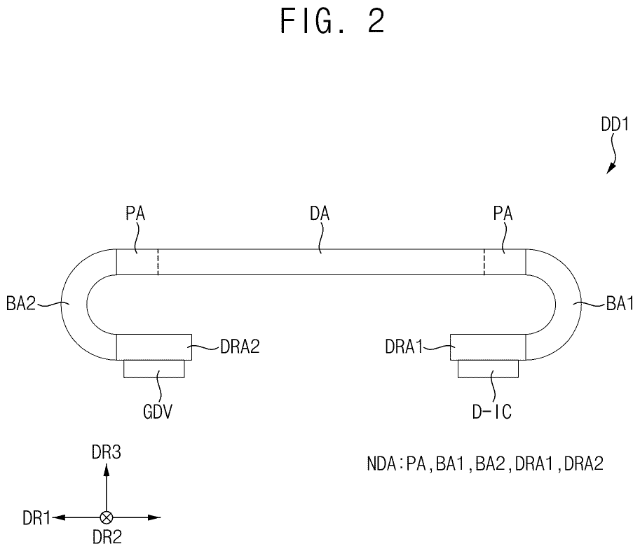

FIG. 1 is a plan view illustrating a display device according to a first embodiment of the present disclosure. FIG. 2 is a side view illustrating a bent shape of the display device of FIG. 1.

In this specification, a plane may be defined by a first direction DR1 and a second direction DR2 intersecting the first direction DR1. For example, the first direction DR1 and the second direction DR2 may be perpendicular to each other. The first direction DR1 may refer to an up-ward direction (or vertical direction) in a plan view. That is, one side of the first direction DR1 may refer to an upward direction in a plan view, and the other side of the first direction DR1 may refer to a downward direction in a plan view. The second direction DR2 may refer to a left-right direction (or horizontal direction) in a plan view. That is, one side of the second direction DR2 may refer to a left direction in a plan view, and the other side of the second direction DR2 may refer to a right direction in a plan view. A direction normal to the plane formed by the first direction and the second direction, that is, a thickness direction of a display device DD1 may be a third direction DR3. In other words, the third direction DR3 may be perpendicular to each of the first direction DR1 and the second direction DR2.

Referring to FIGS. 1 and 2, the display device DD1 according to a first embodiment of the present disclosure may include a substrate SUB, a first driver D-IC, a pad portion PD, a second driver GDV, and data lines DL.

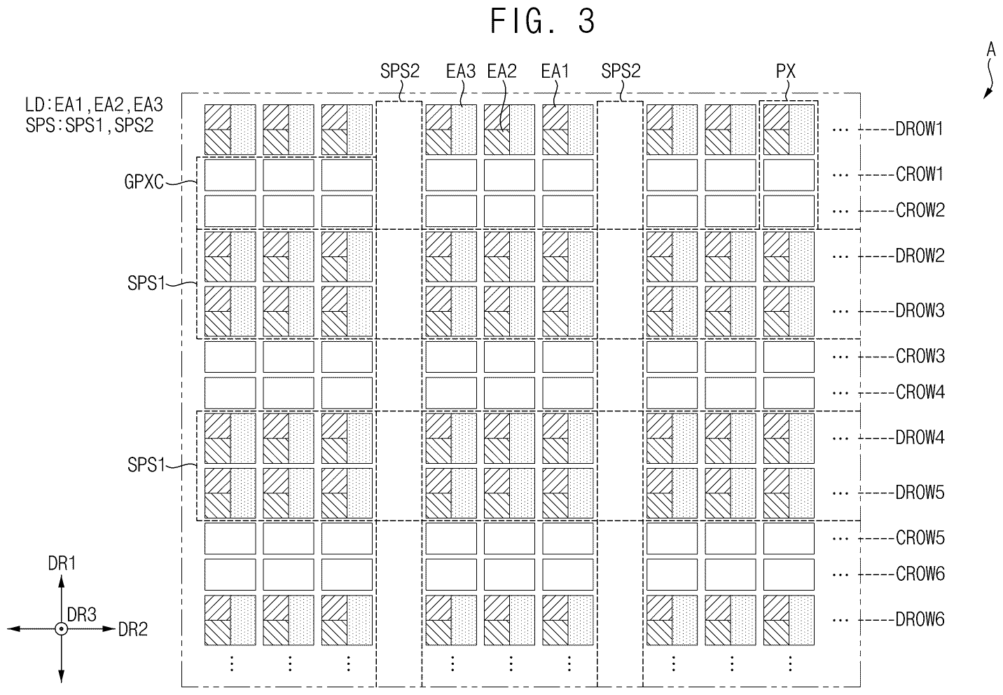

The substrate SUB may include a display area DA and a non-display area NDA. The display area DA may be defined as an area that displays an image by generating light or adjusting the transmittance of light provided from an external light source. A plurality of pixels (e.g., pixels PX of FIG. 3) may be disposed in the display area DA. The pixels may generate light according to a driving signal. The pixels may be arranged in a matrix form along the first direction DR1 and the second direction DR2. A detailed description thereof will be provided below with reference to FIG. 3.

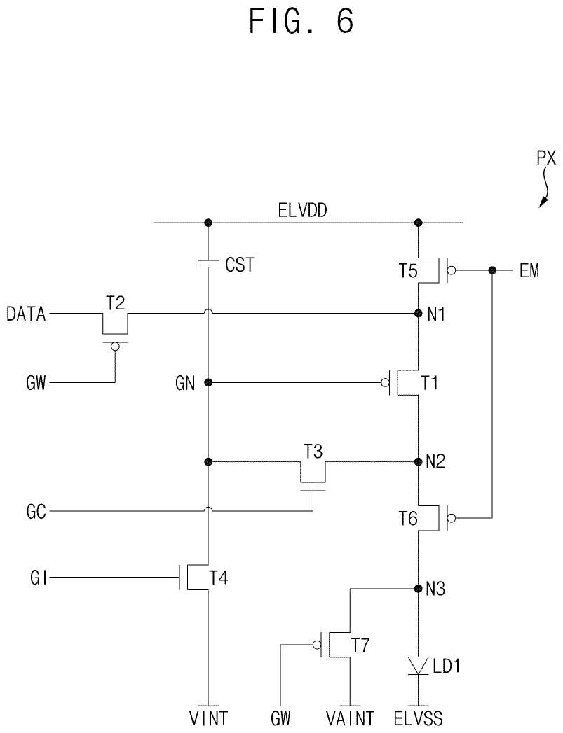

The data lines DL connected to the pixels may be disposed on the substrate SUB in the display area DA. The data lines DL may extend along the first direction DR1 and be disposed along the second direction DR2. Each of the data lines DL may be electrically connected to the first driver D-IC. Each of the data lines DL may receive a data voltage (e.g., a data voltage DATA of FIG. 6) from the first driver D-IC.

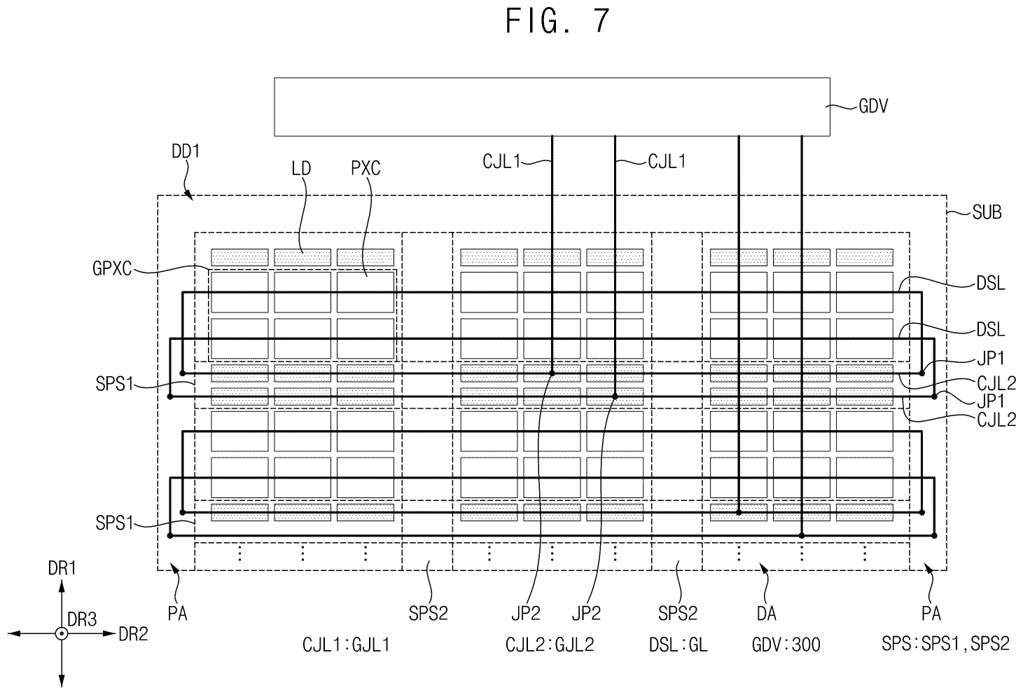

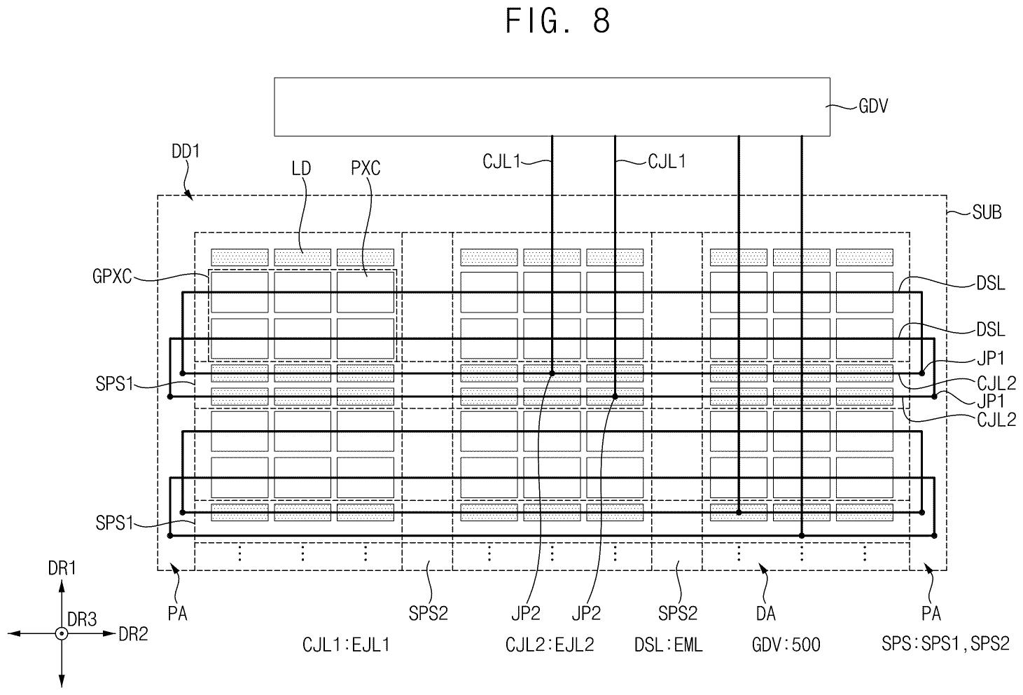

Gate signal lines (e.g., a gate signal line GL of FIG. 7) and emission signal lines (e.g., an emission signal line EML of FIG. 8) which are connected to the pixels may be disposed on the substrate SUB in the display area DA. A detailed description thereof will be provided below with reference to FIGS. 7 and 8.

The non-display area NDA may be defined as an area that does not display an image. The non-display area NDA may surround the display area DA. The non-display area NDA may include a peripheral area PA, bending areas BA, a first driver area DRA1, and a second driver area DRA2.

The peripheral area PA may be positioned around the display area DA. For example, the peripheral area PA may entirely surround the display area DA.

The bending areas BA may include a first bending area BA1 and a second bending area BA2. The first bending area BA1 may extend from one side of the peripheral area PA. For example, the first bending area BA1 may be positioned below the peripheral area PA. The second bending area BA2 may extend from the other side of the peripheral area PA which is disposed opposite to the one side. For example, the second bending area BA2 may be positioned above the peripheral area PA. In a plan view, the first driver area DRA1 may extend from the first bending area BA1 and be positioned below the display area DA or the peripheral area PA. In a plan view, the second driver area DRA2 may extend from the second bending area BA2 and be positioned above the display area DA or the peripheral area PA.

The substrate SUB may be bent about a reference axis parallel to the second direction DR2 in the bending areas BA. In this case, as illustrated in FIG. 2, each of the first driver area DRA1 and the second driver area DRA2 may be positioned on a lower surface of the display device DD1.

As illustrated in FIG. 1, when the display device DD1 is unfolded (i.e., when the substrate SUB is unfolded), the first bending area BA1 may be positioned between the display area DA and the first driver area DRA1, and the second bending area BA2 may be positioned between the display area DA and the second driver area DRA2. Specifically, when the display device DD1 is unfolded, the first bending area BA1 may be positioned between the peripheral area PA and the first driver area DRA1, and the second bending area BA2 may be positioned between the peripheral area PA and the second driver area DRA2.

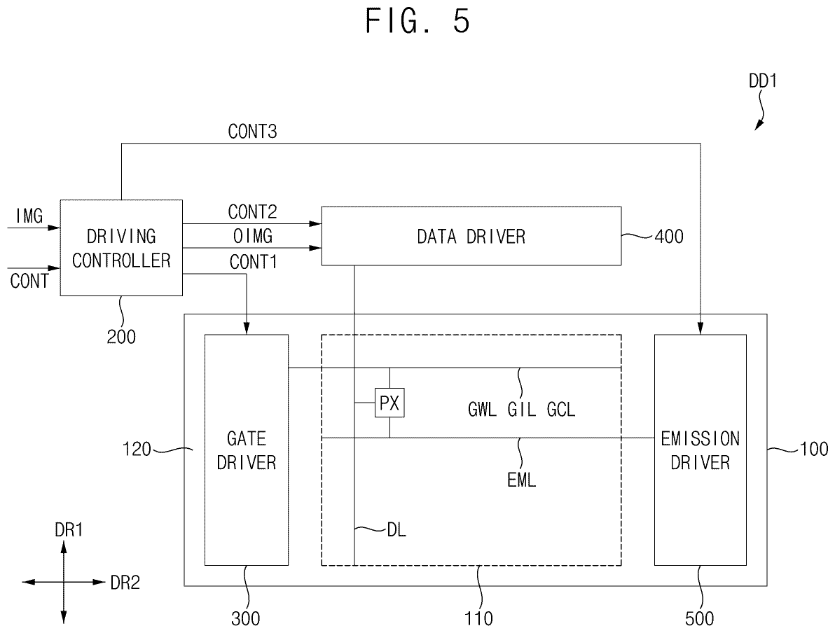

The first driver D-IC may be disposed on the substrate SUB in the non-display area NDA and may be positioned on one side of the display area DA. Specifically, the first driver D-IC may be positioned on the substrate SUB in the first driver area DRA1. The first driver D-IC may convert a digital data signal among the driving signals into an analog data signal and may provide the converted data signal to the pixels. In other words, the first driver D-IC may provide the data voltage to the pixels. For example, the first driver D-IC may serve as a data driver (e.g., a data driver 400 of FIG. 5).

The pad portion PD may be disposed on the substrate SUB in the first driver area DRA1. The pad portion PD may include a plurality of pads. The pad portion PD may be electrically connected to the first driver D-IC and/or a printed circuit board.

The second driver GDV may be disposed on the substrate SUB in the non-display area NDA and may be positioned on the other side of the display area DA which is disposed opposite to the one side of the display area DA. Specifically, the second driver GDV may be positioned on the substrate SUB in the second driver area DRA2. The second driver GDV may provide a driving signal to the pixels. The driving signal may include a gate signal and a light emitting control signal. For example, the second driver GDV may serve as a gate driver (e.g., a gate driver 300 of FIG. 5) and an emission driver (e.g., an emission driver 500 of FIG. 5).

The second driver GDV may be positioned in the first direction DR1 from the display area DA. In other words, the second driver GDV may be disposed adjacent to the display area DA in the first direction DR1. As described above, as the substrate SUB is bent in the second bending area BA2, the second driver GDV may be positioned on the lower surface of the display device DD1. Accordingly, compared to a case where the second driver GDV is positioned in the second direction DR2 from the display area DA, the dead space of the display device DD1 may be reduced.

FIG. 3 is an enlarged plan view of area ‘A’ of FIG. 1.

Referring to FIGS. 1 and 3, the display device DD1 according to the first embodiment of the present disclosure may include the plurality of pixels PX disposed on the substrate SUB in the display area DA. The pixels PX may be arranged in a matrix form along the first direction DR1 and the second direction DR2. Each of the pixels PX may include a light emitting element LD and one of pixel circuits PXC.

The light emitting elements LD may be arranged in a matrix form along the first direction DR1 and the second direction DR2. In other words, the light emitting elements LD may be arranged along a plurality of rows and a plurality of columns. For example, the light emitting elements LD may be arranged along first to sixth element rows DROW1, DROW2, DROW3, DROW4, DROW5, and DROW6. The first to sixth element rows DROW1, DROW2, DROW3, DROW4, DROW5, and DROW6 may be arranged along the first direction DR1.

Each of the light emitting elements LD may include a first light emitting area EA1, a second light emitting area EA2, and a third light emitting area EA3 that emit light. In FIG. 3, each of the light emitting elements LD is illustrated as including three light emitting areas EA1, EA2, and EA3, but the present disclosure is not limited thereto. For example, each of light emitting elements LD may include four or more light emitting areas.

For example, each of the first light emitting area EA1, the second light emitting area EA2, and the third light emitting area EA3 may have a triangular planar shape, a rectangular planar shape, a circular planar shape, a track-shaped planar shape, an ellipse planar shape etc. In an embodiment, each of the first light emitting area EA1, the second light emitting area EA2, and the third light emitting area EA3 may have a rectangular planar shape. However, the present disclosure is not limited thereto, and each of the first light emitting area EA1, the second light emitting area EA2, and the third light emitting area EA3 may have different planar shapes.

In an embodiment, a size (i.e., an area) of the first light emitting area EA1 may be the same as a size of the second light emitting area EA2, and a size of the third light emitting area EA3 may be greater than the size of the first light emitting area EA1 and the size of the second light emitting area EA2. However, the present disclosure is not limited thereto, and the first light emitting area EA1, the second light emitting area EA2, and the third light emitting area EA3 may have the same size.

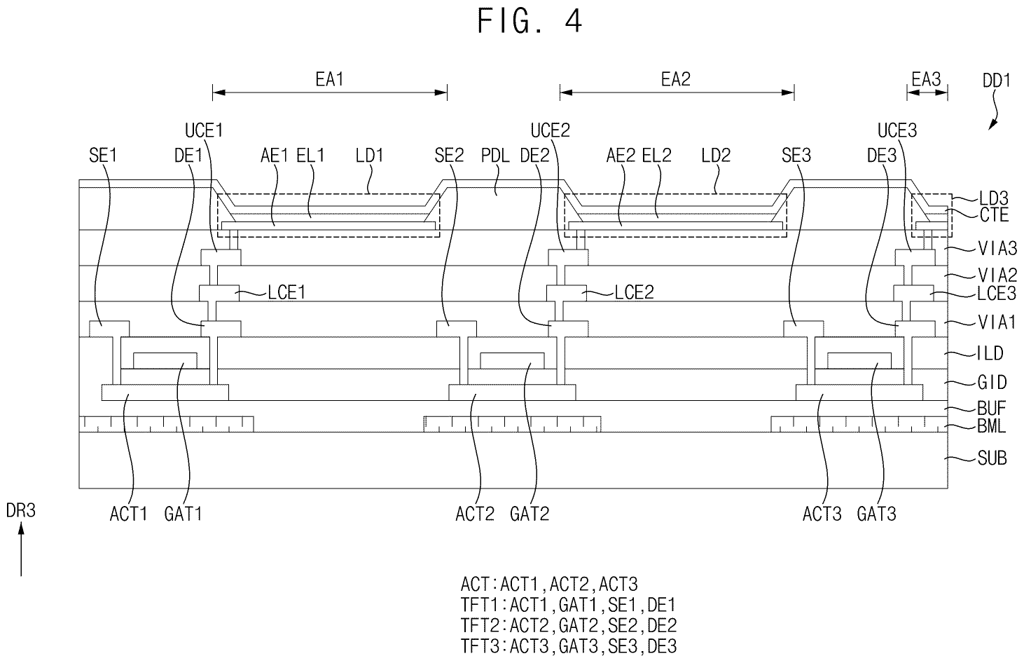

A first light emitting element (e.g., a first light emitting element LD1 of FIG. 4) that emits a first light may be positioned in the first light emitting area EA1. A second light emitting element (e.g., a second light emitting element LD2 of FIG. 4) that emits a second light may be positioned in the second light emitting area EA2. A third light emitting element (e.g., a third light emitting element LD3 of FIG. 4) that emits a third light may be positioned in the third light emitting area EA3. For example, the first light may be red light, the second light may be blue light, and the third light may be green light. However, the present disclosure is not limited thereto.

The pixel circuits PXC may be arranged in a matrix form along the first direction DR1 and the second direction DR2. In other words, the pixel circuits PXC may be arranged along the plurality of rows and the plurality of columns. For example, the pixel circuits PXC may be arranged along first to sixth circuit rows CROW1, CROW2, CROW3, CROW4, CROW5, and CROW6. The first to sixth circuit rows CROW1, CROW2, CROW3, CROW4, CROW5, and CROW6 may be arranged along the first direction DR1.

Each of the pixel circuits PXC may include a first pixel circuit, a second pixel circuit, and a third pixel circuit. The first pixel circuit may be connected to the first light emitting element, the second pixel circuit may be connected to the second light emitting element, and the third pixel circuit may be connected to the third light emitting element. Accordingly, the first pixel circuit may provide a first driving current to the first light emitting element, the second pixel circuit may provide a second driving current to the second light emitting element, and the third pixel circuit may provide a third driving current to the third light emitting element.

The light emitting elements LD positioned in the first element row DROW1 may be respectively connected to the pixel circuits PXC positioned in the first circuit row CROW1. The light emitting elements LD positioned in the second element row DROW2 may be respectively connected to the pixel circuits PXC positioned in the second circuit row CROW2. For example, the first element row DROW1 may be disposed adjacent to the first circuit row CROW1 in the first direction DR1, and the second element row DROW2 may be disposed adjacent to the second circuit row CROW2 in the first direction DR1. In addition, the first circuit row CROW1 and the second circuit row CROW2 may be disposed between the first element row DROW1 and the second element row DROW2. In other words, the first element row DROW1, the first circuit row CROW1, the second circuit row CROW2, and the second element row DROW2 may be sequentially arranged along the first direction DR1.

Similarly, the light emitting elements LD positioned in the third element row DROW3 may be respectively connected to the pixel circuits PXC positioned in the third circuit row CROW3. The light emitting elements LD positioned in the fourth element row DROW4 may be respectively connected to the pixel circuits PXC positioned in the fourth circuit row CROW4. For example, the third element row DROW3 may be disposed adjacent to the third circuit row CROW3 in the first direction DR1, and the fourth element row DROW4 may be disposed adjacent to the fourth circuit row CROW4 in the first direction DR1. In addition, the third circuit row CROW3 and the fourth circuit row CROW4 may be disposed between the third element row DROW3 and the fourth element row DROW4. In other words, the third element row DROW3, the third circuit row CROW3, the fourth circuit row CROW4, and the fourth element row DROW4 may be sequentially arranged along the first direction DR1.

Similarly, the light emitting elements LD positioned in the fifth element row DROW5 may be respectively connected to the pixel circuits PXC positioned in the fifth circuit row CROW5. The light emitting elements LD positioned in the sixth element row DROW6 may be respectively connected to the pixel circuits PXC positioned in the sixth circuit row CROW6. For example, the fifth element row DROW5 may be disposed adjacent to the fifth circuit row CROW5 in the first direction DR1, and the sixth element row DROW6 may be disposed adjacent to the sixth circuit row CROW6 in the first direction DR1. In addition, the fifth circuit row CROW5 and the sixth circuit row CROW6 may be disposed between the fifth element row DROW5 and the sixth element row DROW6. In other words, the fifth element row DROW5, the fifth circuit row CROW5, the sixth circuit row CROW6, and the sixth element row DROW6 may be sequentially arranged along the first direction DR1.

A pixel circuit group GPXC which is a set of the pixel circuits PXC may be disposed between element rows. For example, as illustrated in FIG. 3, one pixel circuit group GPXC may include six pixel circuits PXC arranged along two rows and three columns. However, the number of the pixel circuits PXC included in one pixel circuit group GPXC is not limited thereto.

The pixel circuit groups GPXC may be arranged in a matrix form along the first direction DR1 and the second direction DR2. In other words, the pixel circuit groups GPXC may be arranged along the plurality of rows and the plurality of columns. The pixel circuit groups GPXC may be spaced apart from each other by a predetermined distance. That is, a separation space SPS in which the pixel circuits PXC are not disposed may be defined between the pixel circuit groups GPXC.

The separation space SPS may include a first separation space SPS1 and a second separation space SPS2. The first separation space SPS1 may be a separation space between the pixel circuit groups GPXC arranged along the first direction DR1. In other words, the first separation space SPS1 may be spaced apart from each other in the up-down direction, the first direction DR1, between the pixel circuit groups GPXC in a plan view.

The second separation space SPS2 may be a separation space between the pixel circuit groups GPXC arranged along the second direction DR2. In other words, the second separation space SPS2 may be space spaced apart from each other in the left-right direction, the second direction DR2, between the pixel circuit groups GPXC in a plan view.

In an embodiment, the light emitting elements LD may be positioned in the separation space SPS between the pixel circuit groups GPXC. For example, the light emitting elements LD may be positioned in the first separation space SPS1.

FIG. 4 is a cross-sectional view illustrating the display device of FIG. 1.

Referring to FIG. 4, the display device DD1 according to the first embodiment of the present disclosure may include the substrate SUB, a lower pattern BML, a buffer layer BUF, an active layer ACT, a gate insulating layer GID, first to third gate electrodes GAT1, GAT2, and GAT3, an inter-layer insulating layer ILD, first to third source electrodes SE1, SE2, and SE3, first to third drain electrodes DE1, DE2, and DE3, a first via-insulating layer VIA1, first to third lower connection electrodes LCE1, LCE2, and LCE3, a second via-insulating layer VIA2, first to third upper connection electrodes UCE1, UCE2, and UCE3, a third via-insulating layer VIA3, first to third light emitting element LD1, LD2 and LD3, and a pixel defining layer PDL. The first light emitting element LD1 may include a first pixel electrode AE1, a first light emitting layer EL1, and a common electrode CTE. The second light emitting element LD2 may include a second pixel electrode AE2, a second light emitting layer EL2, and the common electrode CTE. The third light emitting element LD3 may include a third pixel electrode AE3, a third light emitting layer EL3, and the common electrode CTE.

The substrate SUB may include a transparent material or an opaque material. The substrate SUB may be formed of a transparent resin substrate. A polyimide substrate may be an example of the transparent resin substrate. In this case, the polyimide substrate may include a first organic layer, a first barrier layer, a second organic layer, etc. Alternatively, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The lower pattern BML may be disposed on the substrate SUB. The lower pattern BML may include a metal, an alloy, a metal nitride, a conductive metal oxide, a transparent conductive material, etc. Examples of materials that may be used as the lower pattern BML may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other.

The buffer layer BUF may be disposed on the substrate SUB. The buffer layer BUF may prevent diffusion of metal atoms or impurities from the substrate SUB to an upper structure (e.g., the light emitting element LD). In addition, the buffer layer BUF may serve to improve flatness of a surface of the substrate SUB when the surface of the substrate SUB is not uniform. For example, the buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), etc. These may be used alone or in combination with each other.

The active layer ACT may be disposed on the buffer layer BUF. The active layer ACT may include an oxide semiconductor, a silicon semiconductor, an organic semiconductor, etc. For example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, etc. In an embodiment, the active layer ACT may include a silicon semiconductor. The active layer ACT may include a first active pattern ACT1, a second active pattern ACT2, and a third active pattern ACT3. The first active pattern ACT1 may include a first source area, a first drain area, and a first channel area positioned between the first source area and the first drain area. The second active pattern ACT2 may include a second source area, a second drain area, and a second channel area positioned between the second source area and the second drain area. The third active pattern ACT3 may include a third source area, a third drain area, and a third channel area positioned between the third source area and the third drain area.

The gate insulating layer GID may be disposed on the buffer layer BUF and the active layer ACT. The gate insulating layer GID may cover the active layer ACT on the substrate SUB, and may have a substantially flat upper surface without creating a step difference around the active layer ACT. Alternatively, the gate insulating layer GID may cover the active layer ACT on the substrate SUB and may be disposed along the profile of the active layer ACT with a uniform thickness. The gate insulating layer GID may include an inorganic insulating material. Examples of the inorganic insulating materials that may be used as the gate insulating layer GID may include silicon oxide (SiOₓ), silicon nitride (SiNₓ), silicon oxynitride (SiOₓN_{y}), etc. These may be used alone or in combination with each other.

Each of the first to third gate electrodes GE1, GE2, and GE3 may be disposed on the gate insulating layer GID. The first gate electrode GE1 may overlap the first channel area of the first active pattern ACT1. The second gate electrode GE2 may overlap the second channel area of the second active pattern ACT2. The third gate electrode GE3 may overlap the third channel area of the third active pattern ACT3. Each of the first to third gate electrodes GE1, GE2, and GE3 may include a metal, an alloy, a metal nitride, a conductive metal oxide, a transparent conductive material, etc. These may be used alone or in combination with each other.

The inter-layer insulating layer ILD may be disposed on the gate insulating layer GID. The inter-layer insulating layer ILD may cove the first to third gate electrodes GE1, GE2, and GE3 on the gate insulating layer GID, and may have a substantially flat upper surface without creating a step difference around the first to third gate electrodes GE1, GE2, and GE3. Alternatively, the inter-layer insulating layer ILD may cover the first to third gate electrodes GE1, GE2, and GE3 on the gate insulating layer GID and may be disposed along the profiles of the first to third gate electrodes GE1, GE2, and GE3 with a uniform thickness. The inter-layer insulating layer ILD may include an inorganic insulating material. Examples of the inorganic insulating material that may be used as an inter-layer insulating layer ILD may include silicon oxide (SiOₓ), silicon nitride (SiNₓ), silicon oxynitride (SiOₓN_{y}), etc. These may be used alone or in combination with each other.

The first to third source electrodes SE1, SE2, and SE3 and the first to third drain electrodes DE1, DE2, and DE3 may be disposed on the inter-layer insulating layer ILD. The first source electrode SE1 may be connected to the first source area of the first active pattern ACT1 through a contact hole formed through the gate insulating layer GID and the inter-layer insulating layer ILD in the third direction DR3. The first drain electrode DE1 may be connected to the first drain area of the first active pattern ACT1 through a contact hole formed through the gate insulating layer GID and the inter-layer insulating layer ILD in the third direction DR3. The second source electrode SE2 may be connected to the second source area of the second active pattern ACT2 through a contact hole formed through the gate insulating layer GID and the inter-layer insulating layer ILD in the third direction DR3. The second drain electrode DE2 may be connected to the second drain area of the second active pattern ACT2 through a contact hole formed through the gate insulating layer GID and the inter-layer insulating layer ILD in the third direction DR3. The third source electrode SE3 may be connected to the third source area of the third active pattern ACT3 through a contact hole formed through the gate insulating layer GID and the inter-layer insulating layer ILD in the third direction DR3. The third drain electrode DE3 may be connected to the third drain area of the third active pattern ACT3 through a contact hole formed through the gate insulating layer GID and the inter-layer insulating layer ILD in the third direction DR3. Each of the first to third source electrodes SE1, SE2, and SE3 and the first to third drain electrodes DE1, DE2, and DE3 may include a metal, an alloy, a metal nitride, a conductive metal oxide, a transparent conductive material, etc. can do. These may be used alone or in combination with each other.

Accordingly, a first thin film transistor TFT1 including the first active pattern ACT1, the first gate electrode GE1, the first source electrode SE1, and the first drain electrode DE1 may be formed. In addition, a second thin film transistor TFT2 including the second active pattern ACT2, the second gate electrode GE2, the second source electrode SE2, and the second drain electrode DE2 may be formed. In addition, a third thin film transistor TFT3 including the third active pattern ACT3, the third gate electrode GE3, the third source electrode SE3, and the third drain electrode DE3 may be formed. Each of the first to third thin film transistors TFT1, TFT2, and TFT3 may serve as a driving transistor. In other words, each of the first to third thin film transistors TFT1, TFT2, and TFT3 may correspond to a first transistor Tl which is illustrated in FIG. 6.

The first via-insulating layer VIA1 may be disposed on the inter-layer insulating layer ILD on the first to third source electrodes SE1, SE2, and SE3 and the first to third drain electrodes DE1, DE2, and DE3. The first via-insulating layer VIA1 may be disposed on the inter-layer insulating layer ILD with a relatively thick thickness to sufficiently cover the first to third source electrodes SE1, SE2, and SE3 and the first to third drain electrodes DE1, DE2, and DE3. The first via-insulating layer VIA1 may include an organic insulating material. Examples of the organic insulating material that may be used as the first via-insulating layer VIA1 may include photoresist, polyacryl-based resin, polyimide-based resin, polyamide-based resin, siloxane-based resin, acryl-based resin, epoxy-based resin, etc. These may be used alone or in combination with each other.

The first to third lower connection electrodes LCE1, LCE2, and LCE3 may be disposed on the first via-insulating layer VIA1. The first lower connection electrode LCE1 may be connected to the first drain electrode DE1 through a contact hole formed through the first via-insulating layer VIA1 in the third direction DR3. The second lower connection electrode LCE2 may be connected to the second drain electrode DE2 through a contact hole formed through the first via-insulating layer VIA1 in the third direction DR3. The third lower connection electrode LCE3 may be connected to the third drain electrode DE3 through a contact hole formed through the first via-insulating layer VIA1 in the third direction DR3. For example, each of the first to third lower connection electrodes LCE1, LCE2, and LCE3 may include a metal, an alloy, a metal nitride, a conductive metal oxide, a transparent conductive material, etc. These may be used alone or in combination with each other.

The second via-insulating layer VIA2 may be disposed on the first via-insulating layer VIA1 on the first to third lower connection electrodes LCE1, LCE2, and LCE3. The second via-insulating layer VIA2 may be disposed with a relatively thick thickness to sufficiently cover the first to third lower connection electrodes LCE1, LCE2, and LCE3. The second via-insulating layer VIA2 may include an organic insulating material. Examples of the organic insulating material that may be used as the second via-insulating layer VIA2 may include photoresist, polyacryl-based resin, polyimide-based resin, polyamide-based resin, siloxane-based resin, acryl-based resin, epoxy-based resin, etc. These may be used alone or in combination with each other.

The first to third upper connection electrodes UCE1, UCE2, and UCE3 may be disposed on the second via-insulating layer VIA2. The first upper connection electrode UCE1 may be connected to the first lower connection electrode LCE1 through a contact hole formed through the second via-insulating layer VIA2 in the third direction DR3. The second upper connection electrode UCE2 may be connected to the second lower connection electrode LCE2 through a contact hole formed through the second via-insulating layer VIA2 in the third direction DR3. The third upper connection electrode UCE3 may be connected to the third lower connection electrode LCE3 through a contact hole formed through the second via-insulating layer VIA2 in the third direction DR3. For example, each of the first to third upper connection electrodes UCE1, UCE2, and UCE3 may include a metal, an alloy, a metal nitride, a conductive metal oxide, a transparent conductive material, etc. These may be used alone or in combination with each other.

Accordingly, the first lower connection electrode LCE1 and the first upper connection electrode UCE1 may electrically connect the first thin film transistor TFT1 and the first light emitting element LD1. The second lower connection electrode LCE2 and the second upper connection electrode UCE2 may electrically connect the second thin film transistor TFT2 and the second light emitting element LD2. The third lower connection electrode LCE3 and the third upper connection electrode UCE3 may electrically connect the third thin film transistor TFT3 and the third light emitting element LD3.

The third via-insulating layer VIA3 may be disposed on the second via-insulating layer VIA2 on the first to third upper connection electrodes UCE1, UCE2, and UCE3. The third via-insulating layer VIA3 may be disposed with a relatively thick thickness to sufficiently cover the first to third upper connection electrodes UCE1, UCE2, and UCE3. The third via-insulating layer VIA3 may include an organic insulating material. Examples of the organic insulating material that may be used as the third via-insulating layer VIA3 may include photoresist, polyacryl-based resin, polyimide-based resin, polyamide-based resin, siloxane-based resin, acryl-based resin, epoxy-based resin, etc. These may be used alone or in combination with each other.

The first to third pixel electrodes AE1, AE2, and AE3 may be disposed on the third via-insulating layer VIA3. The first pixel electrode AE1 may be connected to the first upper connection electrode UCE1 through a contact hole formed through the third via-insulating layer VIA3 in the third direction DR3. The second pixel electrode AE2 may be connected to the second upper connection electrode UCE2 through a contact hole formed through the third via-insulating layer VIA3 in the third direction DR3. The third pixel electrode AE3 may be connected to the third upper connection electrode UCE3 through a contact hole formed through the third via-insulating layer VIA3 in the third direction DR3. Each of the first to third pixel electrodes AE1, AE2, and AE3 may include a metal, an alloy, a metal nitride, a conductive metal oxide, a transparent conductive material, etc. These may be used alone or in combination with each other. For example, each of the first to third pixel electrodes AE1, AE2, and AE3 may serve as an anode electrode.

The pixel defining layer PDL may be disposed on the third via-insulating layer VIA3 on the first to third pixel electrodes AE1, AE2, and AE3. The pixel defining layer PDL may covers edges of each of the first to third pixel electrodes AE1, AE2, and AE3 and may expose a portion of an upper surface of each of the first to third pixel electrodes AE1, AE2, and AE3. The pixel defining layer PDL may include an organic insulating material. Examples of the organic insulating material that may be used as the pixel defining layer PDL may include photoresist, polyacryl-based resin, polyimide-based resin, polyamide-based resin, siloxane-based resin, acryl-based resin, epoxy-based resin, etc. These may be used alone or in combination with each other. In an embodiment, the pixel defining layer PDL may include an inorganic or an organic material including a light blocking material with black color.

The first light emitting layer EL1 may be disposed on the first pixel electrode AE1, the second light emitting layer EL2 may be disposed on the second pixel electrode AE2, and the third light emitting layer EL3 may be disposed on the third pixel electrode AE3. In addition, the first light emitting layer EL1 may overlap the first light emitting area EA1, the second light emitting layer EL2 may overlap the second light emitting area EA2, and the third light emitting layer EL3 may overlap the third light emitting area EA3. The first to third light emitting layers EL1, EL2, and EL3 may include an organic material that emits light of a preset color. For example, the first light emitting layer EL1 may include an organic material that emits red light, the second light emitting layer EL2 may include an organic material that emits blue light, and the third light emitting layer EL3 may include an organic material that emits green light. However, the present disclosure is not limited thereto.

The common electrode CTE may be disposed on the pixel defining layer PDL on the first to third light emitting layers EL1, EL2, and EL3. The common electrode CTE may include a metal, an alloy, a metal nitride, a conductive metal oxide, a transparent conductive material, etc. These may be used alone or in combination with each other. For example, the common electrode CTE may serve as a cathode electrode.

Accordingly, the first light emitting element LD1 including the first pixel electrode AE1, the first light emitting layer EL1, and the common electrode CTE may be formed. In addition, the second light emitting element LD2 including the second pixel electrode AE2, the second light emitting layer EL2, and the common electrode CTE may be formed. In addition, the third light emitting element LD3 including the third pixel electrode AE3, the third light emitting layer EL3, and the common electrode CTE may be formed.

An encapsulation layer (not shown) may be disposed on the common electrode CTE. The encapsulation layer may prevent impurities, moisture, etc. from penetrating into the first to third light emitting elements LD1, LD2, and LD3 from the outside. The encapsulation layer may include at least one inorganic layer and at least one organic layer. For example, the inorganic layer may include silicon oxide (SiOₓ), silicon nitride (SiNₓ), silicon oxynitride (SiOₓN_{y}), etc. These may be used alone or in combination with each other. For example, the organic layer may include a cured polymer such as polyacrylate.

Although the display device DD1 including the organic light emitting display (OLED) device is illustrated as an example, the configuration of the present disclosure is not limited thereto. In other embodiments, the display device DD1 may include a liquid crystal display (LCD) device, a field emission display (FED) device, a plasma display panel (PDP) device, an electrophoretic image display (EPD) device, an inorganic light emitting display (ILED) device, or a quantum dot display device.

FIG. 5 is a block diagram illustrating the display device of FIG. 1.

Referring to FIG. 5, the display device DD1 may include a display panel 100 and a display panel driver. The display panel 100 may include a display portion 110 that displays an image and a peripheral portion 120 disposed adjacent to the display portion 110. The peripheral portion 120 may include a gate driver 300 and an emission driver 500. The display panel driver may drive the display panel 100. The display panel driver may include a drive controller 200, a gate driver 300, and a data driver 400.

The display panel 100 may include gate signal lines GWL, GIL, and GCL, data lines DL, emission signal lines EML, and the pixels PX connected to the gate signal lines GWL, GIL, and GCL, the data lines DL, and the emission signal lines EML.

The gate signal lines GWL, GIL, and GCL and the emission signal lines EML may extend in the second direction DR2. The data lines DL may extend in the first direction DR1.

The driving controller 200 may receive an input image data IMG and an input control signal CONT from a host processor (e.g., a graphic processing unit (GPU)). For example, the input image data IMG may include a red image data, a green image data, and a blue image data. The input control signal CONT may include a master clock signal, a data enable signal, etc. The input control signal CONT may further include a vertical synchronization signal and a horizontal synchronization signal.

The driving controller 200 may generate a first control signal CONT1, a second control signal CONT2, a third control signal CONT3, and an output image data OIMG based on the input image data IMG and the input control signal CONT.

The driving controller 200 may generate the first control signal CONT1 for controlling the operation of the gate driver 300 based on the input control signal CONT and may output the first control signal CONT1 to the gate driver 300. The first control signal CONT1 may include a vertical start signal and a gate clock signal.

The driving controller 200 may generate the second control signal CONT2 for controlling the operation of the data driver 400 based on the input control signal CONT and may output the second control signal CONT2 to the data driver 400. The second control signal CONT2 may include a horizontal start signal and a load signal.

The driving controller 200 may generate the third control signal CONT3 for controlling the operation of the emission driver 500 based on the input control signal CONT and may output the third control signal CONT3 to the emission driver 500. The third control signal CONT3 may include a vertical start signal and an emission clock signal.

The driving controller 200 may receive the input image data IMG and the input control signal CONT and may generate the output image data OIMG. The driving controller 200 may output the output image data OIMG to the data driver 400.

The gate driver 300 may generate gate signals for driving the gate signal lines GWL, GIL, and GCL in response to the first control signal CONT1 received from the driving controller 200. The gate signals may include a write gate signal (e.g., a write gate signal GW of FIG. 6), an initialization gate signal (e.g., an initialization gate signal GI of FIG. 6), and a compensation gate signal (e.g., a compensation gate signal GC of FIG. 6).

The gate signal lines may include write gate lines GWL, initialization gate lines GIL, and compensation gate lines GCL. For example, the gate driver 300 may output the write gate signal to the write gate lines GWL. The gate driver 300 may output the initialization gate signal to the initialization gate lines GIL. The gate driver 300 may output the compensation gate signal to the compensation gate lines GCL.

The data driver 400 may receive the second control signal CONT2 and the output image data OIMG from the drive controller 200. The data driver 400 may generate a data voltage (e.g., a data voltage DATA of FIG. 6) by converting the output image data OIMG into an analog voltage. The data driver 400 may output the data voltage to the data lines DL.

The emission driver 500 may receive the third control signal CONT3 from the driving controller 200. The emission driver 500 may generate an emission control signal (e.g., an emission control signal EM of FIG. 6) for driving the emission signal lines EML. The emission driver 500 may output the emission control signal to the emission signal lines EML.

In FIG. 5, the gate driver 300 is illustrated as being disposed on a first side of the display portion 110 and the emission driver 500 is illustrated as being disposed on a second side of the display portion 110 for convenience of description. However, the present disclosure is not limited thereto. For example, both the gate driver 300 and the emission driver 500 may be disposed on the first side of the display portion 110 or the gate driver 300 and the data driver 400 may be disposed to face each other with the display portion 110 disposed therebetween. In an embodiment, the gate driver 300 and the emission driver 500 may be formed integrally. The first driver D-IC which is illustrated in FIG. 1 may serve as the data driver 400, and the second driver GDV which is illustrated in FIG. 1 may serve as the gate driver 300 and the emission driver 500.

FIG. 6 is a circuit diagram illustrating a pixel included in the display device of FIG. 1.

Referring to FIG. 6, each of the pixels PX may include the first light emitting element LD1 and the first pixel circuit, and the first pixel circuit may include first to seventh transistors T1, T2, T3, T4, T5, T6, and T7 and a storage capacitor CST. However, the present disclosure is not limited thereto. For example, some of the configurations of the pixel circuit PXC may be omitted, and other configurations may be added to the pixel circuit PXC. The description of the first light emitting element LD1 and the first pixel circuit may replace the description of the second light emitting element LD2 which is illustrated in FIG. 4 and the second pixel circuit. In addition, the description of the first light emitting element LD1 and the first pixel circuit may replace the description of the third light emitting element LD3 which is illustrated in FIG. 4 and the third pixel circuit.

The first transistor T1 may include a gate electrode, a first electrode, and a second electrode. The gate electrode of the first transistor T1 may be connected to a gate node GN. The first electrode of the first transistor T1 may be connected to a first node N1. The second electrode of the first transistor T1 may be connected to a second node N2. The first transistor T1 may generate a driving current based on the voltage difference between the gate electrode and the first electrode. For example, the first transistor T1 may be referred to as a driving transistor.

The second transistor T2 may include a gate electrode, a first electrode, and a second electrode. The gate electrode of the second transistor T2 may receive a write gate signal GW. The second transistor T2 may be turned on or off in response to the write gate signal GW which is supplied to the gate electrode of the second transistor T2. The first electrode of the second transistor T2 may receive a data voltage VDATA. The second electrode of the second transistor T2 may be connected to the first node N1. While the second transistor T2 is turned on, the second transistor T2 may provide the data voltage VDATA to the first electrode of the first transistor T1. For example, the second transistor T2 may be referred to as a write transistor.

The third transistor T3 may include a gate electrode, a first electrode, and a second electrode. The third transistor T3 may be connected between the gate electrode of the first transistor T1 and the second electrode of the first transistor T1. That is, the first electrode of the third transistor T3 may be connected to the gate node GN, and the second electrode of the third transistor T3 may be connected to the second node N2. The gate electrode of the third transistor T3 may receive a compensation gate signal GC. The third transistor T3 may be turned on or off in response to the compensation gate signal GC. While the third transistor T3 is turned on, the third transistor T3 may diode-connect the first transistor T1. That is, the third transistor T3 may compensate for the threshold voltage of the first transistor T1. For example, the third transistor T3 may be referred to as a compensation transistor.

As illustrated in FIG. 6, the third transistor T3 may have a single transistor structure. Alternatively, the third transistor T3 may have a dual transistor structure in which two transistors are connected in series.

The fourth transistor T4 may include a gate electrode, a first electrode, and a second electrode. The gate electrode of the fourth transistor T4 may receive an initialization gate signal GI. The fourth transistor T4 may be turned on or off in response to the initialization gate signal GI which is supplied to the gate electrode of the fourth transistor T4. The first electrode of the fourth transistor T4 may be provided with a gate initialization voltage VINT. The second electrode of the fourth transistor T4 may be connected to the gate node GN. While the fourth transistor T4 is turned on, the gate initialization voltage VINT may be provided to the gate electrode of the first transistor T1. For example, the fourth transistor T4 may be referred to as a gate initialization transistor.

As illustrated in FIG. 6, the fourth transistor T4 may have a single transistor structure. Alternatively, the fourth transistor T4 may have a dual transistor structure in which two transistors are connected in series.

The fifth transistor T5 may include a gate electrode, a first electrode, and a second electrode. The gate electrode of the fifth transistor T5 may receive an emission control signal EM. The fifth transistor T5 may be turned on or off in response to the emission control signal EM. The first electrode of the fifth transistor T5 may be provided with a driving voltage ELVDD. The second electrode of the fifth transistor T5 may be connected to the first node N1. While the fifth transistor T5 is turned on, the fifth transistor T5 may provide the driving voltage ELVDD to the first electrode of the first transistor T1. For example, the fifth transistor T5 may be referred to as a first emission control transistor.

The sixth transistor T6 may include a gate electrode, a first electrode, and a second electrode. The gate electrode of the sixth transistor T6 may receive the emission control signal EM. The sixth transistor T6 may be turned on or off in response to the emission control signal EM. The first electrode of the sixth transistor T6 may be connected to the second node N2. The second electrode of the sixth transistor T6 may be connected to a third node N3. While the sixth transistor T6 is turned on, the sixth transistor T6 may provide the driving current generated by the first transistor T1 to the first light emitting element LD1. For example, the sixth transistor T6 may be referred to as a second emission control transistor.

The seventh transistor T7 may include a gate electrode, a first electrode, and a second electrode. The gate electrode of the seventh transistor T7 may receive the write gate signal GW. The seventh transistor T7 may be turned on or off in response to the write gate signal GW. The first electrode of the seventh transistor T7 may be provided with an anode initialization voltage VAINT. The second electrode of the seventh transistor T7 may be connected to the third node N3. While the seventh transistor T7 is turned on, the seventh transistor T7 may provide the anode initialization voltage VAINT to an anode electrode of the first light emitting element LD1. For example, the seventh transistor T7 may be referred to as an anode initialization transistor.

In an embodiment, each of the first transistor T1, the second transistor T2, the fifth transistor T5, the sixth transistor T6, and the seventh transistor T7 may be a PMOS transistor, and each of the third transistor T3 and the fourth transistor T4 may be an NMOS transistor.

Accordingly, an active pattern of each of the first transistor T1, the second transistor T2, the fifth transistor T5, the sixth transistor T6, and the seventh transistor T7 may include a cation-doped silicon semiconductor. An active pattern of each of the third transistor T3 and the fourth transistor T4 may include an oxide semiconductor.

The write gate signal GW for turning on each of the second transistor T2 and the seventh transistor T7 may have a low level. The emission control signal EM for turning on each of the fifth transistor T5 and the sixth transistor T6 may have a low level. The compensation gate signal GC for turning on the third transistor T3 may have a high level. The initialization gate signal GI for turning on the fourth transistor T4 may have a high level.

The storage capacitor CST may include a first electrode and a second electrode. The first electrode of the storage capacitor CST may be provided with the driving voltage ELVDD. The second electrode of the storage capacitor CST may be connected to the gate node GN. The storage capacitor CST may maintain the voltage level of the gate electrode of the first transistor T1 even when the second transistor T2 is turned off.

The first light emitting element LD1 may include the anode electrode and a cathode electrode. The anode electrode of the first light emitting element LD1 may be connected to the third node N3. The cathode electrode of the first light emitting element LD1 may be provided with a common voltage ELVSS. The first light emitting element LD1 may generate light with a luminance corresponding to the driving current.

FIGS. 7, 8, 9, and 10 are plan views illustrating the display device of FIG. 1.

Referring to FIGS. 7 and 8, the display device DD1 according to the first embodiment of the present disclosure may include the substrate SUB, the second driver GDV, the light emitting elements LD, the pixel circuit groups GPXC, the data lines, a first connection line CJL1, a second connection line CJL2, and a signal line DSL.

The pixel circuit groups GPXC may be disposed on the substrate SUB in the display area DA. The pixel circuit groups GPXC may be arranged in a matrix form along the first direction DR1 and the second direction DR2. The pixel circuit groups GPXC may be spaced apart from each other by a predetermined distance. That is, the separation space SPS in which the pixel circuits PXC are not disposed may be defined between the pixel circuit groups GPXC. The separation space SPS may include the first separation space SPS1 and the second separation space SPS2. The first separation space SPS1 may be a separation space between the pixel circuit groups GPXC arranged along the first direction DR1. The second separation space SPS2 may be a separation space between the pixel circuit groups GPXC arranged along the second direction DR2.

The light emitting elements LD may be disposed on the substrate SUB in the display area DA. The light emitting elements LD may be arranged in a matrix form along the first direction DR1 and the second direction DR2. In addition, the light emitting elements LD may be positioned in the separation space SPS, for example, the first separation space SPS1, between the pixel circuit groups GPXC.

The second driver GDV may be disposed on the substrate SUB in the non-display area (e.g., the non-display area NDA of FIG. 1). Specifically, the second driver GDV may be disposed on the substrate SUB in the second driver area (e.g., the second driver area DRA2 of FIG. 1). The second driver GDV may provide a driving signal to the pixel circuits PXC.

The first connection line CJL1 may be connected to the second driver GDV and may extend in the first direction DR1. Specifically, the first connection line CJL1 may be connected to the second driver GDV in the non-display area. The first connection line CJL1 may receive the driving signal from the second driver GDV. The first connection line CJL1 may include a metal, an alloy, a metal nitride, a conductive metal oxide, a transparent conductive material, etc. These may be used alone or in combination with each other. In an embodiment, the first connection line CJL1 may be disposed in the same layer as the first to third lower connection electrodes LCE1, LCE2, and LCE3 which are disposed on the first via-insulating layer VIA1 of FIG. 4. That is, the first connection line CJL1 may be formed using the same material and through the same process as the first to third lower connection electrodes LCE1, LCE2, and LCE3 of FIG. 4.

The second connection line CJL2 may be connected to the first connection line CJL1 and may extend in the second direction DR2. Specifically, the second connection line CJL2 may be connected to the first connection line CJL1 in the display area DA at a second contact point JP2. More specifically, the second connection line CJL2 may be connected to the first connection line CJL1 in the separation space SPS, for example, the first separation space SPS1, between the pixel circuit groups GPXC at the second contact point JP2. The second connection line CJL2 may receive the driving signal via the first connection line CJL1.

In an embodiment, the second contact point JP2 may be positioned in the first separation space SPS1 between the pixel circuit groups GPXC arranged along the first direction DR1. In other words, the second contact point JP2 may be positioned in a space spaced apart in the up-down direction between the pixel circuit groups GPXC in a plan view. In this case, the second connection line CJL2 may be spaced apart from the pixel circuits PXC in a plan view. In addition, at least a portion of the second connection line CJL2 may overlap the light emitting elements LD in a plan view.

The second connection line CJL2 may include a metal, an alloy, a metal nitride, a conductive metal oxide, a transparent conductive material, etc. In an embodiment, the second connection line CJL2 may include aluminum (Al), copper (Cu), silver (Ag), molybdenum (Mo), titanium (Ti), etc. That is, the second connection line CJL2 may include a low-resistance metal. These may be used alone or in combination with each other.

In an embodiment, the second connection line CJL2 may be disposed in the same layer as the first to third source electrodes SE1, SE2, and SE3 and the first to third drain electrodes DE1, DE2, and DE3 which are disposed on the inter-layer insulating layer ILD of FIG. 4.

That is, the second connection line CJL2 may be formed using the same material and through the same process as the first to third source electrodes SE1, SE2, and SE3 and the first to third drain electrodes DE1, DE2, and DE3 of FIG. 4.

The signal line DSL may be connected to the second connection line CJL2. In an embodiment, the signal line DSL may include a portion extending in the second direction DR2 and a portion extending in the first direction DR1. For example, the signal line DSL may extend in the second direction DR2 at the display area DA and may extend in the first direction DR1 at the non-display area. Specifically, the signal line DSL may be connected to the second connection line CJL2 in the non-display area at a first contact point JP1. The signal line DSL may receive the driving signal via the second connection line CJL2. The signal line DSL may overlap the pixel circuits PXC positioned in the same row (i.e., the pixel circuits PXC arranged along the second direction DR2) in a plan view. The signal line DSL may transmit the driving signal to the pixel circuits PXC positioned in the same row. The signal line DSL may include a metal, an alloy, a metal nitride, a conductive metal oxide, a transparent conductive material, etc. These may be used alone or in combination with each other.

In an embodiment, the second driver GDV may be positioned in the first direction DR1 from the display area DA, and the first contact point JP1 may be positioned in the second direction DR2 from the display area DA. For example, the second driver GDV may be positioned on the upper side of the non-display area which is disposed adjacent to the display area DA in the first direction DR1. The first contact point JP1 may be positioned on the left and/or right side of the non-display area which is disposed adjacent to the display area DA in the second direction DR2. In other words, the first contact point JP1 may be positioned on the left and/or right side of the peripheral area PA.

Although not illustrated in FIGS. 7 and 8, the data lines (e.g., the data lines DL of FIG. 1) may extend in the first direction DR1 and may be disposed along the second direction DR2. Each of the data lines may be connected to the first driver (e.g., the first driver D-IC of FIG. 1). Each of the data lines may receive the data voltage from the first driver. Each of the data lines may overlap the pixel circuits PXC positioned in the same column (i.e., the pixel circuits PXC arranged along the first direction DR1) in a plan view. Each of the data lines may transmit the data voltage to the pixel circuits PXC positioned in the same column.

In an embodiment, as illustrated in FIG. 7, the second driver GDV may include the gate driver 300 which provides a gate signal, the first connection line CJL1 may include a first gate connection line GJL1 connected to the gate driver 300, and the second connection line CJL2 may include a second gate connection line GJL2 connected to the first gate connection line GJL1. In addition, the signal line DSL may include a gate signal line GL which is connected to the second gate connection line GJL2 and transmits the gate signal provided from the gate driver 300. The second gate connection line GJL2 may be connected to the first gate connection line GJL1 in the first separation space SPS1 at the second contact point JP2. The gate signal line GL may be connected to the second gate connection line GJL2 on the left and/or right side of the peripheral area PA at the first contact point JP1.

In an embodiment, as illustrated in FIG. 8, the second driver GDV may include the emission driver 500 which provides an emission control signal, the first connection line CJL1 may include a first emission connection line EJL1 connected to the emission driver 500, and the second connection line CJL2 may include a second emission connection line EJL2 connected to the first emission connection line EJL1. In addition, the signal line DSL may include an emission signal line EML which is connected to the second emission connection line EJL2 and transmits the emission control signal provided from the emission driver 500. The second emission connection line EJL2 may be connected to the first emission connection line EJL1 in the first separation space SPS1 at the second contact point JP2. The emission signal line EML may be connected to the second emission connection line EJL2 on the left and/or right side of the peripheral area PA at the first contact point JP1.

When the second connection line CJL2 is connected to the first connection line CJL1 which transmits the driving signal in an area overlapping the pixel circuit PXC in a plan view at the second contact point JP2, the luminance of light emitted by the light emitting element connected to the pixel circuit PXC which overlaps the second contact point JP2 in a plan view may be different from the luminance of light emitted by the light emitting element connected to the pixel circuit PXC which is spaced apart from the second contact point JP2 in a plan view.

Similarly, when the signal line DSL is connected to the second connection line CJL2 which transmits the driving signal in an area overlapping the pixel circuit PXC in a plan view at the first contact point JP1, the luminance of light emitted by the light emitting element connected to the pixel circuit PXC which overlaps the first contact point JP1 in a plan view may be different from the luminance of light emitted by the light emitting element connected to the pixel circuit PXC which is spaced apart from the first contact point JP1 in a plan view. Due to the difference in luminance between the lights emitted by the light emitting elements, display defects such as spots may occur in a display device.

To suppress the display defects in which spots are visible in the display device DD1 according to the first embodiment of the present disclosure, the second connection line CJL2 may be connected to the first connection line CJL1 in the separation space SPS between the pixel circuit groups GPXC at the second contact point JP2, and the signal line DSL may be connected to the second connection line CJL2 in the peripheral area PA at the first contact point JP1. In other words, each of the first contact point JP1 and the second contact point JP2 may be spaced apart from the pixel circuits PXC in a plan view. Accordingly, the luminance difference between the lights emitted by the light emitting elements may be reduced or prevented, and the display defect in which spots are visible in the display device DD1 may be suppressed.

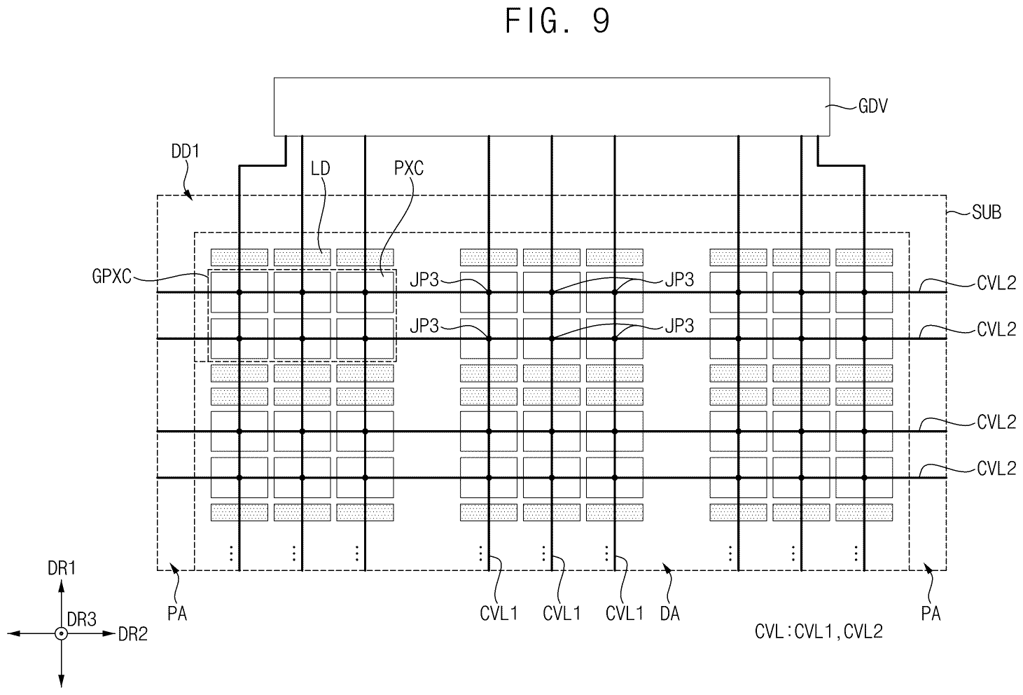

Referring further to FIG. 9, the display device DD1 according to the first embodiment of the present disclosure may further include a constant voltage line CVL. The constant voltage line CVL may include a first constant voltage line CVL1 and a second constant voltage line CVL2.

The first constant voltage line CVL1 may be connected to the second driver GDV and may extend in the first direction DR1. Specifically, the first constant voltage line CVL1 may be connected to the second driver GDV in the non-display area. The first constant voltage line CVL1 may overlap the pixel circuits PXC positioned in the same column (i.e., the pixel circuits PXC arranged along the first direction DR1) in a plan view. The first constant voltage line CVL1 may receive a constant voltage from the second driver GDV. For example, the constant voltage may include the driving voltage ELVDD, the common voltage ELVSS, the gate initialization voltage VINT, and the anode initialization voltage VAINT which are illustrated in FIG. 6.

The second constant voltage line CVL2 may be connected to the first constant voltage line CVL1 and may extend in the second direction DR2. The second constant voltage line CVL2 may overlap the pixel circuits PXC positioned in the same row (i.e., the pixel circuits PXC arranged along the second direction DR2) in a plan view. The second constant voltage line CVL2 may be connected to the first constant voltage line CVL1 in the display area DA at a third contact point JP3. The second constant voltage line CVL2 may receive the constant voltage via the first constant voltage line CVL1. Accordingly, the second constant voltage line CVL2 may transmit the constant voltage to the pixel circuits PXC positioned in the same row.

In an embodiment, the third contact point JP3 may overlap each of the pixel circuits PXC in a plan view. Since the constant voltage line CVL transmits the constant voltage rather than the driving signal, the luminance of light emitted by the light emitting element connected to the pixel circuit PXC which overlaps the third contact point JP3 in a plan view may be same as the luminance of light emitted by the light emitting element connected to the pixel circuit PXC which is spaced apart from the third contact point JP3 in a plan view.

In other words, even if the second constant voltage line CVL2 is connected to the first constant voltage line CVL1, which transmits the constant voltage, in an area overlapping the pixel circuit PXC in a plan view, difference in luminance may not occur between the lights emitted by the light emitting elements.

The constant voltage line CVL may include a metal, an alloy, a metal nitride, a conductive metal oxide, a transparent conductive material, etc. These may be used alone or in combination with each other. In an embodiment, the first constant voltage line CVL1 may be disposed in the same layer as the first to third upper connection electrodes UCE1, UCE2, and UCE3 which are disposed on the second via-insulating layer VIA2 of FIG. 4. That is, the first constant voltage line CVL1 may be formed using the same material and through the same process as the first to third upper connection electrodes UCE1, UCE2, and UCE3 of FIG. 4.

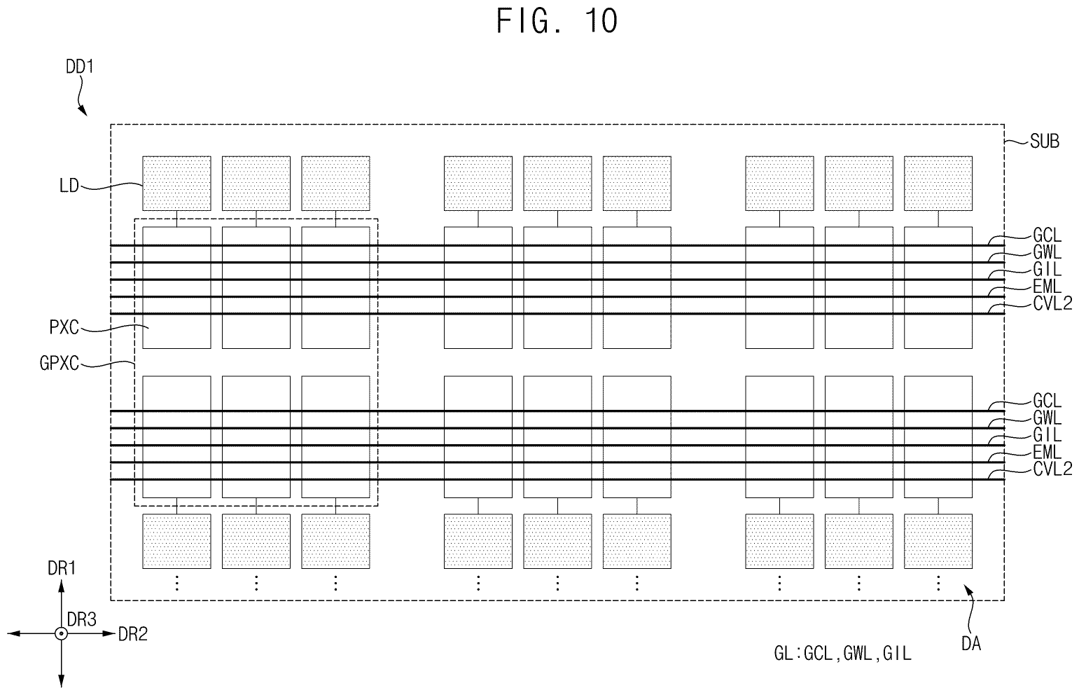

Referring further to FIG. 10, each of the gate signal line GL, the emission signal line EML, and the second constant voltage line CVL2 may extend in the second direction DR2 and may overlap the pixel circuits PXC positioned in the same row in a plan view. In an embodiment, the gate signal line GL, the emission signal line EML, and the second constant voltage line CVL2 may be formed using the same material and through the same process. However, the present disclosure is not limited thereto.

The second driver GDV may provide the gate signal, the emission control signal, and the constant voltage. The gate signal may include the compensation gate signal (e.g., the compensation gate signal GC of FIG. 6), the write gate signal (e.g., the write gate signal GW of FIG. 6), and the initialization gate signal (e.g., the initialization gate signal GI of FIG. 6).

The gate signal line GL may include a compensation gate line GCL, a write gate line GWL, and an initialization gate line GIL. The compensation gate line GCL may transmit the compensation gate signal provided from the second driver GDV to the pixel circuits PXC positioned in the same row. The write gate line GWL may transmit the write gate signal provided from the second driver GDV to the pixel circuits PXC positioned in the same row. The initialization gate line GIL may transmit the initialization gate signal provided from the second driver GDV to the pixel circuits PXC positioned in the same row.

The emission signal line EML may transmit the emission control signal provided from the second driver GDV to the pixel circuits PXC positioned in the same row. The second constant voltage line CVL2 may transmit the constant voltage provided from the second driver GDV to the pixel circuits PXC positioned in the same row.

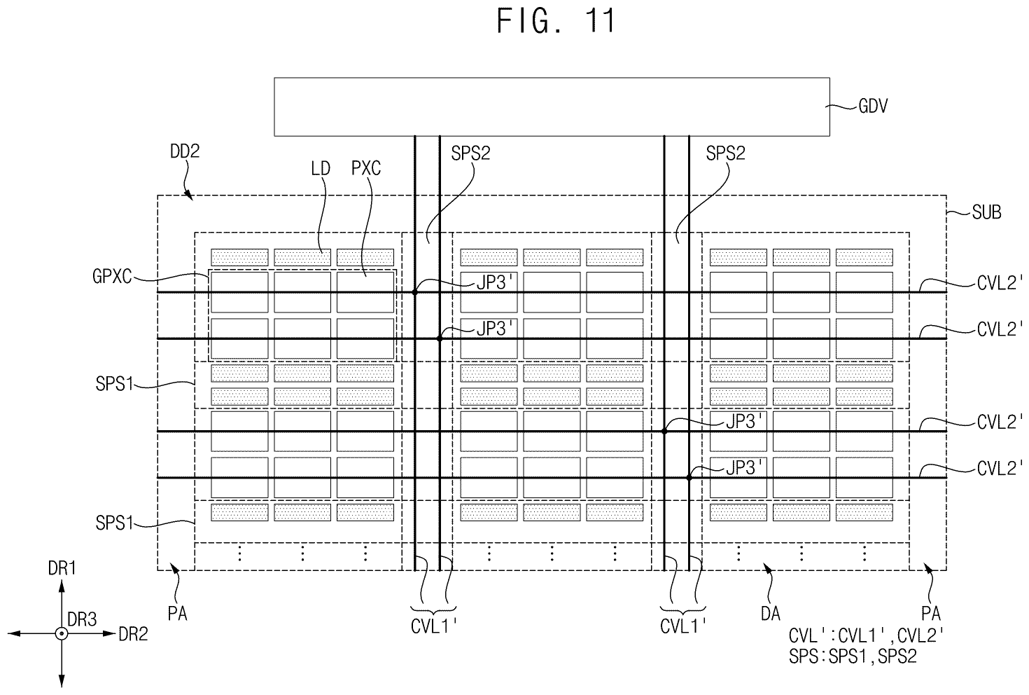

FIG. 11 is a plan view illustrating a display device according to a second embodiment of the present disclosure.

Referring to FIG. 11, a display device DD2 according to a second embodiment of the present disclosure may include the substrate SUB, the second driver GDV, the light emitting elements LD, the pixel circuit groups GPXC, and a constant voltage line CVL′.

The display device DD2, which is illustrated in FIG. 11, may be substantially the same as the display device DD1 described with reference to FIGS. 7, 8, 9, and 10, except for the constant voltage line CVL′. Hereinafter, descriptions overlapping descriptions of the display device DD1 described with reference to FIGS. 7, 8. 9, and 10 will be omitted or simplified.

The constant voltage line CVL′ may include a first constant voltage line CVL1′ and a second constant voltage line CVL2′. The first constant voltage line CVL1′ may be connected to the second driver GDV and may extend in the first direction DR1. In an embodiment, the first constant voltage line CVL1′ may be spaced apart from the pixel circuits PXC in a plan view. The first constant voltage line CVL1′ may receive a constant voltage from the second driver GDV.

The second constant voltage line CVL2′ may be connected to the first constant voltage line CVL1′ and may extend in the second direction DR2. The second constant voltage line CVL2′ may overlap the pixel circuits PXC positioned in the same row in a plan view. The second constant voltage line CVL2′ may be connected to the first constant voltage line CVL1′ in the display area DA at a third contact point JP3′. The second constant voltage line CVL2′ may receive the constant voltage via the first constant voltage line CVL1′. Accordingly, the second constant voltage line CVL2′ may transmit the constant voltage to the pixel circuits PXC positioned in the same row.

In an embodiment, the third contact point JP3′ may be positioned in the separation space SPS between the pixel circuit groups GPXC. For example, the third contact point JP3′ may be positioned in the second separation space SPS2 between the pixel circuit groups GPXC arranged along the second direction DR2. In other words, the third contact point JP3′ may be positioned in a space between pixel circuit groups GPXC arranged in the left-right direction in a plan view.

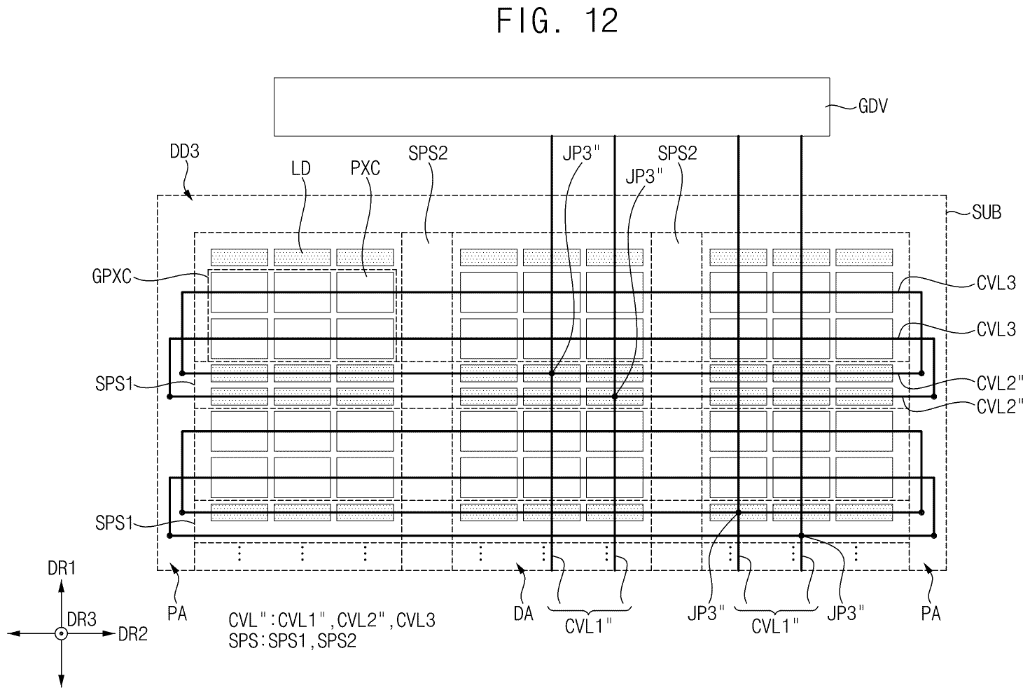

FIG. 12 is a plan view illustrating a display device according to a third embodiment of the present disclosure.

Referring to FIG. 12, a display device DD3 according to a third embodiment of the present disclosure may include the substrate SUB, the second driver GDV, the light emitting elements LD, the pixel circuit groups GPXC, and a constant voltage line CVL″.

The display device DD3, which is illustrated in FIG. 12, may be substantially the same as the display device DD1 described with reference to FIGS. 7, 8, 9, and 10, except for the constant voltage line CVL″. Hereinafter, descriptions overlapping descriptions of the display device DD1 described with reference to FIGS. 7, 8. 9, and 10 will be omitted or simplified.

The constant voltage line CVL″ may include a first constant voltage line CVL1″, a second constant voltage line CVL2″, and a third constant voltage line CVL3. The first constant voltage line CVL1″ may be connected to the second driver GDV and may extend in the first direction DR1. The first constant voltage line CVL1″ may overlap the pixel circuits PXC positioned in the same column in a plan view. The first constant voltage line CVL1″ may receive a constant voltage from the second driver GDV.

The second constant voltage line CVL2″ may be connected to the first constant voltage line CVL1″ and may extend in the second direction DR2. In an embodiment, the second constant voltage line CVL2″ may be spaced apart from the pixel circuits PXC in a plan view. The second constant voltage line CVL2″ may be connected to the first constant voltage line CVL1″ in the display area DA at a third contact point JP3″. The second constant voltage line CVL2″ may receive the constant voltage via the first constant voltage line CVL1″.

In an embodiment, the third contact point JP3″ may be positioned in the separation space SPS between the pixel circuit groups GPXC. For example, the third contact point JP3″ may be positioned in the first separation space SPS1 between the pixel circuit groups GPXC arranged along the first direction DR1. In other words, the third contact point JP3″ may be positioned in a space between the pixel circuit groups GPXC arranged in the up-down direction in a plan view.

The third constant voltage line CVL3 may be connected to the second constant voltage line CVL2″ and may extend in the second direction DR2. Specifically, the third constant voltage line CVL3 may be connected to the second constant voltage line CVL2″ in the peripheral area PA. The third constant voltage line CVL3 may receive the constant voltage via the second constant voltage line CVL2″. The third constant voltage line CVL3 may overlap the pixel circuits PXC positioned in the same row in a plan view. The third constant voltage line CVL3 may transmit the constant voltage to the pixel circuits PXC positioned in the same row.

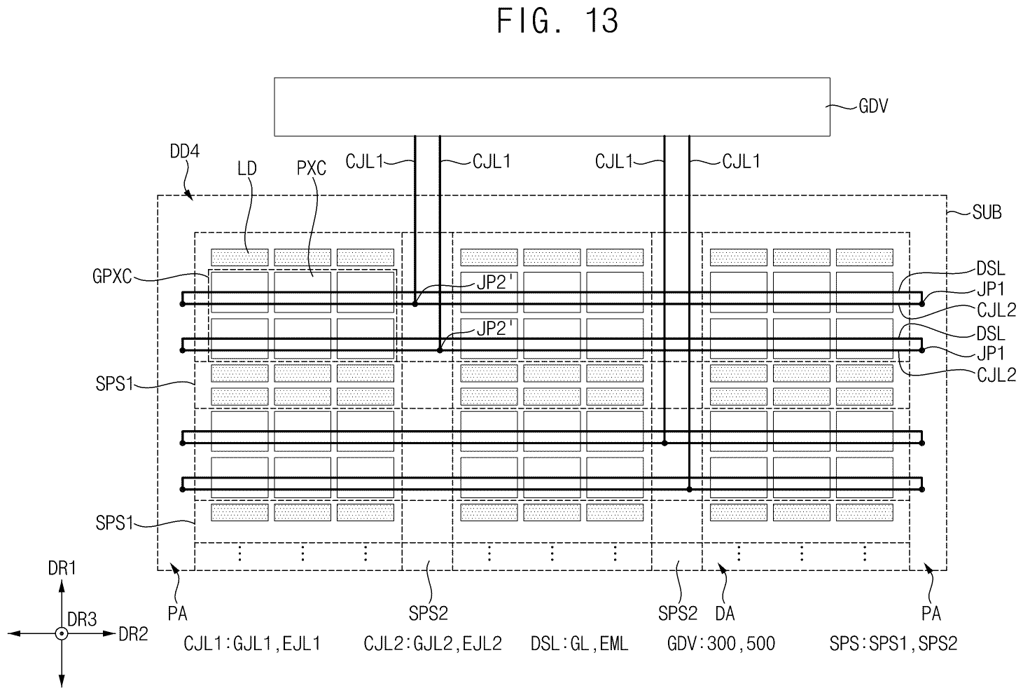

FIG. 13 is a plan view illustrating a display device according to a fourth embodiment of the present disclosure.

Referring to FIG. 13, a display device DD4 according to a fourth embodiment of the present disclosure may include the substrate SUB, the second driver GDV, the light emitting elements LD, the pixel circuit groups GPXC, a first connection line CJL1, a second connection line CJL2, and the signal line DSL.

The display device DD4, which is illustrated in FIG. 13, may be substantially the same as the display device DD1 described with reference to FIGS. 7, 8, 9, and 10, except for the position where the first connection line CJL1 and the second connection line CJL2 are connected. Hereinafter, descriptions overlapping descriptions of the display device DD1 described with reference to FIGS. 7, 8. 9, and 10 will be omitted or simplified.

The first connection line CJL1 may be connected to the second driver GDV and may extend in the first direction DR1. The first connection line CJL1 may receive a driving signal from the second driver GDV. The first connection line CJL1 may include the first gate connection line GJL1 and the first emission connection line EJL1.

The second connection line CJL2 may be connected to the first connection line CJL1 and may extend in the second direction DR2. The second connection line CJL2 may be connected to the first connection line CJL1 in the separation space SPS between the pixel circuit groups GPXC at a second contact point JP2′. The second connection line CJL2 may receive the driving signal via the first connection line CJL1. The second connection line CJL2 may include the second gate connection line GJL2 and the second emission connection line EJL2.

In an embodiment, the second contact point JP2′ may be positioned in the second separation space SPS2 between the pixel circuit groups GPXC arranged along the second direction DR2. In other words, the second contact point JP2′ may be positioned in a space between the pixel circuit groups GPXC arranged in the left-right direction in a plan view. In this case, the first connection line CJL1 may be spaced apart from the pixel circuits PXC in a plan view.

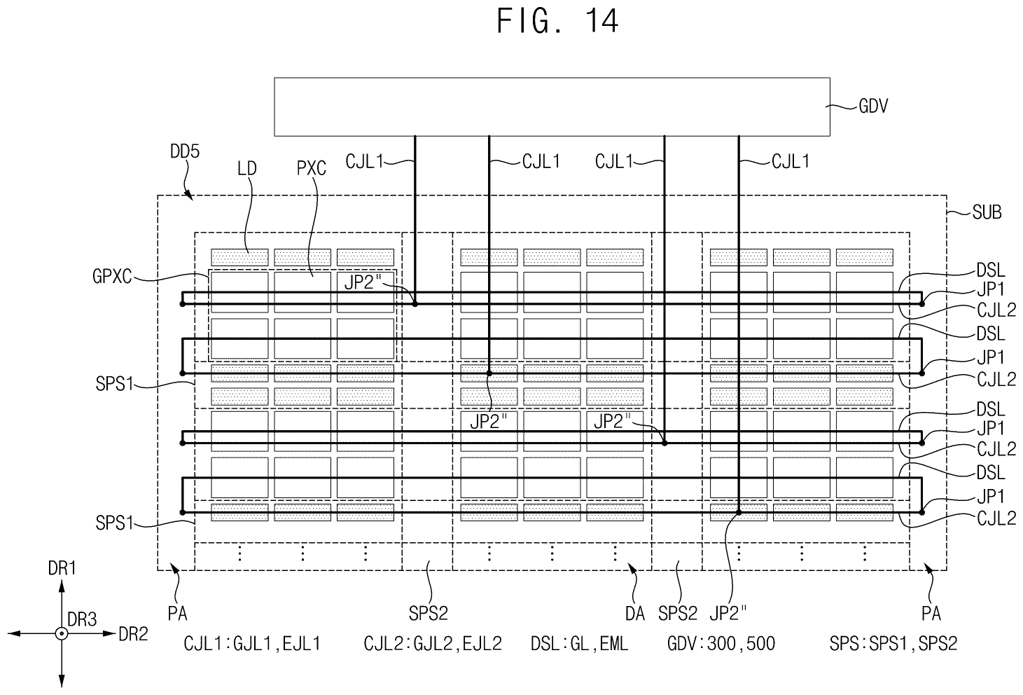

FIG. 14 is a plan view illustrating a display device according to a fifth embodiment of the present disclosure.

Referring to FIG. 14, a display device DD5 according to a fifth embodiment of the present disclosure may include the substrate SUB, the second driver GDV, the light emitting elements LD, the pixel circuit groups GPXC, a first connection line CJL1, a second connection line CJL2, and the signal line DSL.

The display device DD5, which is illustrated in FIG. 14, may be substantially the same as the display device DD1 described with reference to FIGS. 7, 8, 9, and 10, except for the position where the first connection line CJL1 and the second connection line CJL2 are connected. Hereinafter, descriptions overlapping descriptions of the display device DD1 described with reference to FIGS. 7, 8. 9, and 10 will be omitted or simplified.

The first connection line CJL1 may be connected to the second driver GDV and may extend in the first direction DR1. The first connection line CJL1 may receive a driving signal from the second driver GDV. The first connection line CJL1 may include the first gate connection line GJL1 and the first emission connection line EJL1.

The second connection line CJL2 may be connected to the first connection line CJL1 and may extend in the second direction DR2. The second connection line CJL2 may be connected to the first connection line CJL1 in the separation space SPS between the pixel circuit groups GPXC at a second contact point JP2″. The second connection line CJL2 may receive the driving signal via the first connection line CJL1. The second connection line CJL2 may include the second gate connection line GJL2 and the second emission connection line EJL2.

In an embodiment, the second contact point JP2″ may be positioned in the first separation space SPS1 and the second separation space SPS2. In other words, the second contact point JP2″ may be positioned in a space between the pixel circuit groups GPXC arranged in the up-down direction and a space between the pixel circuit groups GPXC arranged in the left-right direction in a plan view. In this case, the second connection line CJL2 forming the second contact point JP2″ in the first separation space SPS1 may be spaced apart from the pixel circuits PXC in a plan view. In addition, the first connection line CJL1 forming the second contact point JP2″ in the second separation space SPS2 may be spaced apart from the pixel circuits PXC in a plan view.

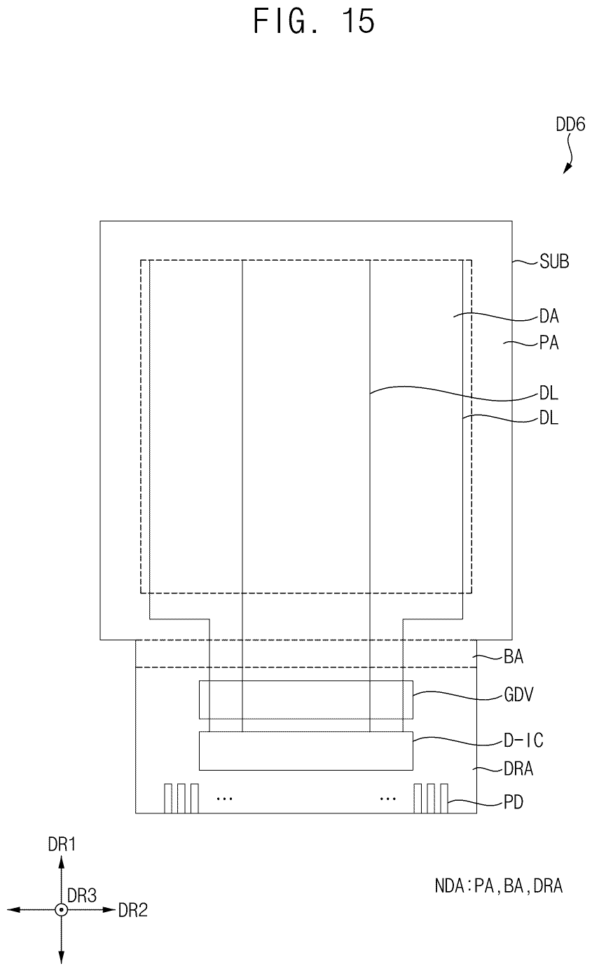

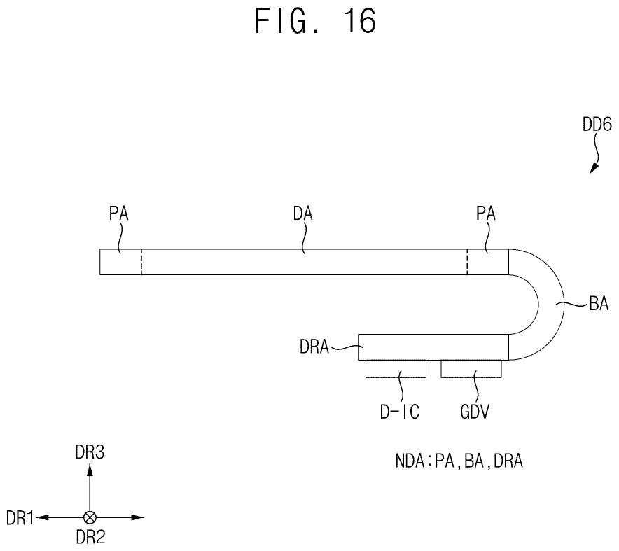

FIG. 15 is a plan view illustrating a display device according to a sixth embodiment of the present disclosure. FIG. 16 is a side view illustrating a bent shape of the display device of FIG. 15.

Referring to FIGS. 15 and 16, a display device DD6 according to a sixth embodiment of the present disclosure may include the substrate SUB, a first driver D-IC, a second driver GDV, the pad portion PD, and the data lines DL.

The display device DD6, which is illustrated in FIG. 15, may be substantially the same as the display device DD1 described with reference to FIGS. 1 to 6, except that the first driver D-IC and the second driver GDV are positioned adjacent to each other. Hereinafter, descriptions overlapping descriptions of the display device DD1 described with reference to FIGS. 1 to 6 will be omitted or simplified.

The substrate SUB may include a display area DA and a non-display area NDA. The display area DA may be defined as an area that displays an image. The non-display area NDA may be defined as an area that does not display an image. The non-display area NDA may surround the display area DA. The non-display area NDA may include a peripheral area PA, a bending area BA, and a driver area DRA.

The peripheral area PA may be positioned around the display area DA. For example, the peripheral area PA may entirely surround the display area DA.

The bending area BA may extend from one side of the peripheral area PA. In a plan view, the driver area DRA may extend from the bending area BA and be positioned below the display area DA or the peripheral area PA. The substrate SUB may be bent about a reference axis parallel to the second direction DR2 in the bending area BA. In this case, as illustrated in FIG. 16, the driver area DRA may be positioned on a lower surface of the display device DD6.

As illustrated in FIG. 15, when the display device DD6 is unfolded (i.e., when the substrate SUB is unfolded), the bending area BA may be positioned between the display area DA and the driver area DRA. Specifically, when the display device DD6 is unfolded, the bending area BA may be positioned between the peripheral area PA and the driver area DRA.

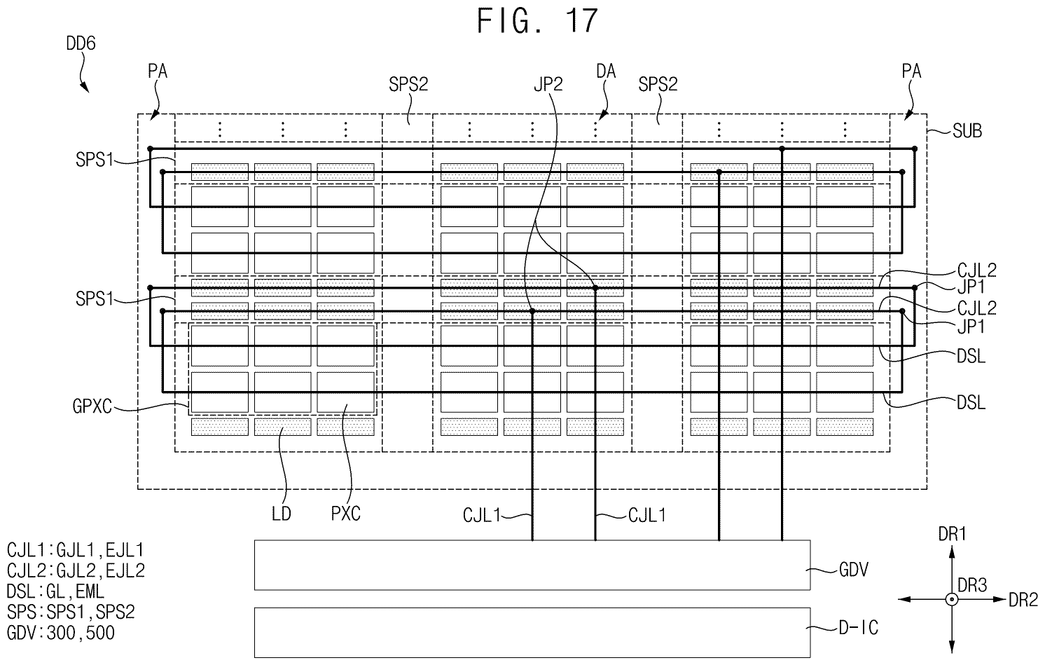

The first driver D-IC may be disposed on the substrate SUB in the non-display area NDA and may be positioned on one side of the display area DA. Specifically, the first driver D-IC may be positioned on the substrate SUB in the driver area DRA. The first driver D-IC may provide a data voltage to pixel circuits (e.g., pixel circuits PXC of FIG. 17). For example, the first driver D-IC may serve as the data driver (e.g., the data driver 400 of FIG. 5).

The pad portion PD may be disposed on the substrate SUB in the driver area DRA. The pad portion PD may be electrically connected to the first driver D-IC and/or a printed circuit board.

The second driver GDV may be disposed on the substrate SUB in the non-display area NDA and be positioned on the one side of the display area DA. Specifically, the second driver GDV may be positioned on the substrate SUB in the driver area DRA. In this case, the pad portion PD, the first driver D-IC, and the second driver GDV may be sequentially arranged along the first direction DR1 in the driver area DRA. The second driver GDV may provide a driving signal to the pixel circuits. The driving signal may include a gate signal and an emission control signal. For example, the second driver GDV may serve as the gate driver (e.g., the gate driver 300 of FIG. 5) and the emission driver (e.g., the emission driver 500 of FIG. 5).

The second driver GDV may be positioned in the first direction DR1 from the display area DA. In other words, the second driver GDV may be disposed adjacent to the display area DA in the first direction DR1. As described above, as the substrate SUB is bent in the bending area BA, the second driver GDV may be positioned on the lower surface of the display device DD6. Accordingly, compared to a case where the second driver GDV is positioned in the second direction DR2 from the display area DA, the dead space of the display device DD6 may be reduced.

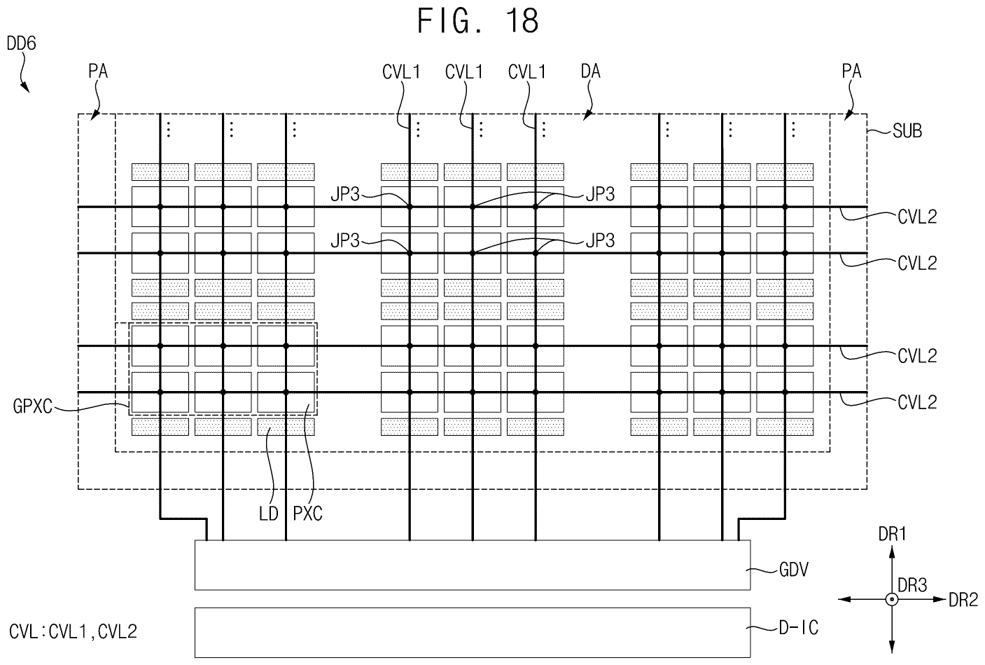

FIGS. 17 and 18 are plan views illustrating the display device of FIG. 15.

Referring to FIGS. 15, 17, and 18, the display device DD6 according to the sixth embodiment of the present disclosure may include the substrate SUB, the first driver D-IC, the second driver GDV, the light emitting elements LD, the pixel circuit groups GPXC, the data lines DL, a first connection line CJL1, a second connection line CJL2, a signal line DSL, and a constant voltage line CVL.

The display device DD6 may be substantially the same as the display device DD1 described with reference to FIGS. 7 to 10, except that the first driver D-IC and the second driver GDV are positioned adjacent to each other. Hereinafter, descriptions overlapping descriptions of the display device DD1 described with reference to FIGS. 7 to 10 will be omitted or simplified.

The pixel circuit groups GPXC may be disposed on the substrate SUB in the display area DA. The pixel circuit groups GPXC may be arranged in a matrix form along the first direction DR1 and the second direction DR2. A separation space SPS in which the pixel circuits PXC are not disposed may be defined between the pixel circuit groups GPXC. The separation space SPS may include the first separation space SPS1 and the second separation space SPS2. The first separation space SPS1 may be defined as a separation space between the pixel circuit groups GPXC arranged along the first direction DR1. The second separation space SPS2 may be defined as a separation space between the pixel circuit groups GPXC arranged along the second direction DR2.

The first driver D-IC may be disposed on the substrate SUB in the non-display area NDA. Specifically, the first driver D-IC may be disposed on the substrate SUB in the driver area DRA. The first driver D-IC may provide a data voltage to the pixel circuits PXC. Although not illustrated in FIGS. 17 and 18, each of the data lines DL may extend in the first direction DR1, and the data lines DL may be disposed along the second direction DR2. Each of the data lines DL may receive the data voltage from the first driver D-IC. Each of the data lines DL may transmit the data voltage to the pixel circuits PXC positioned in the same column.

The second driver GDV may be disposed on the substrate SUB in the non-display area NDA. Specifically, the second driver GDV may be disposed on the substrate SUB in the driver area DRA. In an embodiment, the second driver GDV may be disposed adjacent to the first driver D-IC in the driver area DRA. The second driver GDV may provide a driving signal to the pixel circuits PXC. For example, the driving signal may include the gate signal and the emission control signal. The second driver GDV may include the gate driver 300 which provides the gate signal and the emission driver 500 which provides the emission control signal.

The first connection line CJL1 may be connected to the second driver GDV in the non-display area NDA and may extend in the first direction DR1. The first connection line CJL1 may receive the driving signal from the second driver GDV. The first connection line CJL1 may include the first gate connection line GJL1 and the first emission connection line EJL1.

The second connection line CJL2 may be connected to the first connection line CJL1 and may extend in the second direction DR2. The second connection line CJL2 may be connected to the first connection line CJL1 in the separation space SPS between the pixel circuit groups GPXC at a second contact point JP2. The second connection line CJL2 may receive the driving signal via the first connection line CJL1. The second connection line CJL2 may include the second gate connection line GJL2 and the second emission connection line EJL2.

In an embodiment, the second contact point JP2 may be positioned in the first separation space SPS1 between the pixel circuit groups GPXC arranged along the first direction DR1. In this case, the second connection line CJL2 may be spaced apart from the pixel circuits PXC in a plan view.

The signal line DSL may be connected to the second connection line CJL2. In an embodiment, the signal line DSL may include a portion extending in the second direction DR2 and a portion extending in the first direction DR1. For example, the signal line DSL may extend in the second direction DR2 at the display area DA and may extend in the first direction DR1 at the non-display area NDA. Specifically, the signal line DSL may be connected to the second connection line CJL2 on the left and/or right side of the peripheral area PA at a first contact point JP1. The signal line DSL may receive the driving signal from the second connection line CJL2. The signal line DSL may transmit the driving signal to the pixel circuits PXC positioned in the same row. The signal line DSL may include the gate signal line GL and the emission signal line EML.

As illustrated in FIG. 18, the constant voltage line CVL may include a first constant voltage line CVL1 and a second constant voltage line CVL2. The first constant voltage line CVL1 may be connected to the second driver GDV and may extend in the first direction DR1. The first constant voltage line CVL1 may receive a constant voltage from the second driver GDV. The constant voltage may include the driving voltage ELVDD, the common voltage ELVSS, the gate initialization voltage VINT, and the anode initialization voltage VAINT which are illustrated in FIG. 6.

The second constant voltage line CVL2 may be connected to the first constant voltage line CVL1 and may extend in the second direction DR2. The second constant voltage line CVL2 may be connected to the first constant voltage line CVL1 in the display area DA at a third contact point JP3. The second constant voltage line CVL2 may receive the constant voltage via the first constant voltage line CVL1. Accordingly, the second constant voltage line CVL2 may transmit the constant voltage to the pixel circuits PXC positioned in the same row.

In an embodiment, the third contact point JP3 may overlap each of the pixel circuits PXC in a plan view. In an alternative embodiment, the third contact point JP3 may be positioned in the separation space SPS between the pixel circuit groups GPXC.

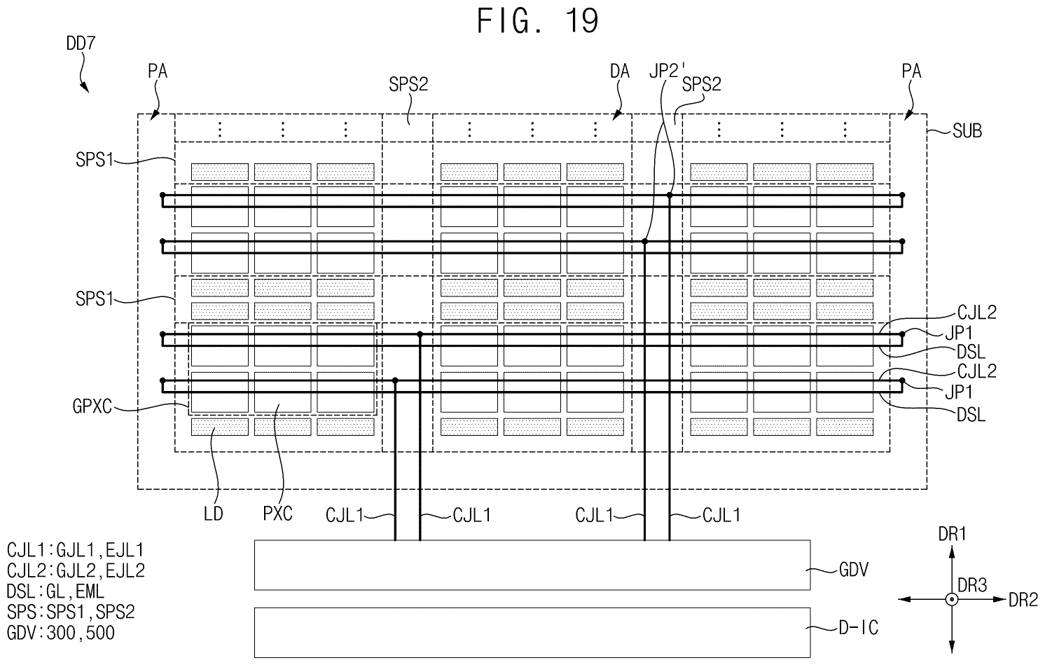

FIG. 19 is a plan view illustrating a display device according to a seventh embodiment of the present disclosure.

Referring to FIG. 19, a display device DD7 according to a seventh embodiment of the present disclosure may include the substrate SUB, the first driver D-IC, the second driver GDV, the light emitting elements LD, the pixel circuit groups GPXC, a first connection line CJL1, a second connection line CJL2, and the signal line DSL.

The display device DD7, which is illustrated in FIG. 19, may be substantially the same as the display device DD6 described with reference to FIGS. 17 and 18, except for the position where the first connection line CJL1 and the second connection line CJL2 are connected. Hereinafter, descriptions overlapping descriptions of the display device DD6 described with reference to FIGS. 17 and 18 will be omitted or simplified.

The first connection line CJL1 may be connected to the second driver GDV and may extend in the first direction DR1. The first connection line CJL1 may receive a driving signal from the second driver GDV. The first connection line CJL1 may include the first gate connection line GJL1 and the first emission connection line EJL1.

The second connection line CJL2 may be connected to the first connection line CJL1 and may extend in the second direction DR2. The second connection line CJL2 may be connected to the first connection line CJL1 in the separation space SPS between the pixel circuit groups GPXC at a second contact point JP2′. The second connection line CJL2 may receive the driving signal via the first connection line CJL1. The second connection line CJL2 may include the second gate connection line GJL2 and the second emission connection line EJL2.

In an embodiment, the second contact point JP2′ may be positioned in the second separation space SPS2 between the pixel circuit groups GPXC arranged along the second direction DR2. In this case, the first connection line CJL1 may be spaced apart from the pixel circuits PXC in a plan view.

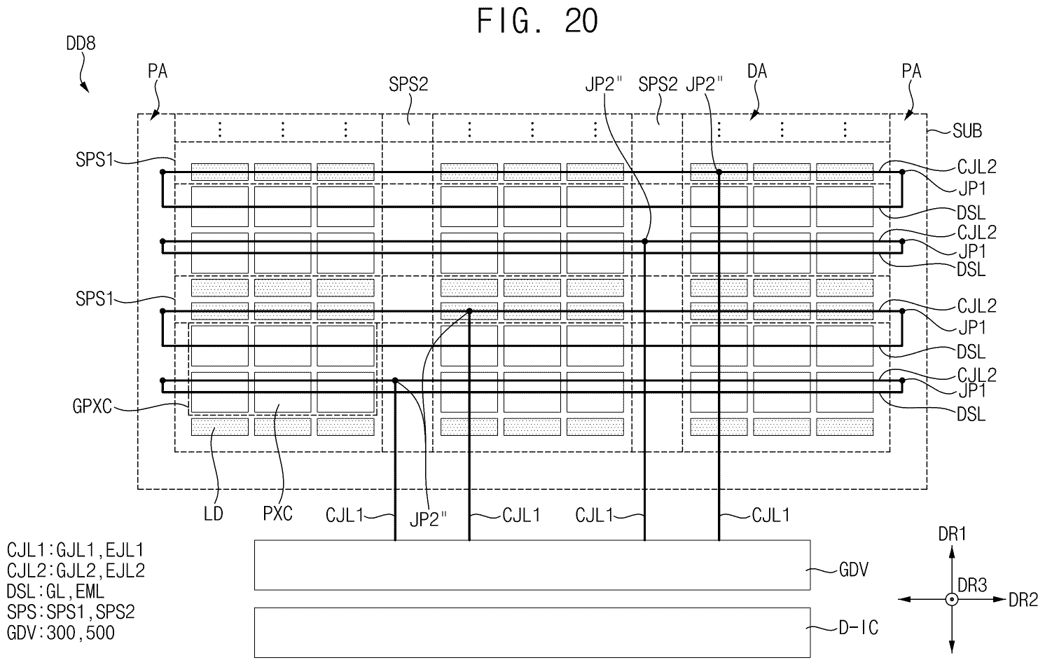

FIG. 20 is a plan view illustrating a display device according to an eighth embodiment of the present disclosure.

Referring to FIG. 20, a display device DD8 according to an eighth embodiment of the present disclosure may include the substrate SUB, the first driver D-IC, the second driver GDV, the light emitting elements LD, the pixel circuit groups GPXC, a first connection line CJL1, a second connection line CJL2, and the signal line DSL.

The display device DD8, which is illustrated in FIG. 20, may be substantially the same as the display device DD6 described with reference to FIGS. 17 and 18, except for the position where the first connection line CJL1 and the second connection line CJL2 are connected. Hereinafter, descriptions overlapping descriptions of the display device DD6 described with reference to FIGS. 17 and 18 will be omitted or simplified.

The first connection line CJL1 may be connected to the second driver GDV and may extend in the first direction DR1. The first connection line CJL1 may receive a driving signal from the second driver GDV. The first connection line CJL1 may include the first gate connection line GJL1 and the first emission connection line EJL1.

The second connection line CJL2 may be connected to the first connection line CJL1 and may extend in the second direction DR2. The second connection line CJL2 may be connected to the first connection line CJL1 in the separation space SPS between the pixel circuit groups GPXC at a second contact point JP2″. The second connection line CJL2 may receive the driving signal via the first connection line CJL1. The second connection line CJL2 may include the second gate connection line GJL2 and the second emission connection line EJL2.

In an embodiment, the second contact point JP2″ may be positioned in the first separation space SPS1 and the second separation space SPS2. In this case, the second connection line CJL2 forming the second contact point JP2″ in the first separation space SPS1 may be spaced apart from the pixel circuits PXC in a plan view. In addition, the first connection line CJL1 forming the second contact point JP2″ in the second separation space SPS2 may be spaced apart from the pixel circuits PXC in a plan view.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a substrate including a display area and a non-display area surrounding the display area;
pixel circuit groups disposed in a matrix form along a first direction and a second direction which intersects the first direction on the substrate in the display area, each of the pixel circuit groups including pixel circuits;
a first driver disposed on the substrate in the non-display area on one side of the display area and providing a data voltage to the pixel circuits;
a second driver disposed on the substrate in the non-display area on the other side which is opposite to the one side of the display area and providing a driving signal to the pixel circuits;
a first connection line connected to the second driver and extending in the first direction;
a second connection line connected to the first connection line in a separation space between adjacent pixel circuit groups and extending in the second direction; and
a signal line connected to the second connection line and transmitting the driving signal provided from the second driver to the pixel circuits.

2. The display device of claim 1, wherein the second connection line and the signal line are connected in the non-display area at a first contact point, and
wherein the first connection line and the second connection line are connected in the display area at a second contact point.

3. The display device of claim 2, wherein the second driver is positioned to be spaced apart from the display area in the first direction, and
wherein the first contact point is positioned in the non-display area to be spaced apart from the display area in the second direction.

4. The display device of claim 2, wherein the second contact point is positioned in a first separation space between the adjacent pixel circuit groups arranged along the first direction.

5. The display device of claim 4, further comprising:
a light emitting element positioned in the separation space between the adjacent pixel circuit groups,
wherein at least a portion of the second connection line overlaps the light emitting element in a plan view.

6. The display device of claim 2, wherein the second contact point is positioned in a second separation space between the adjacent pixel circuit groups arranged along the second direction.

7. The display device of claim 1, wherein the second driver includes a gate driver which provides a gate signal to the pixel circuits,
wherein the first connection line includes a first gate connection line connected to the gate driver,
wherein the second connection line includes a second gate connection line connected to the first gate connection line, and
wherein the signal line includes a gate signal line which is connected to the second gate connection line and transmits the gate signal provided from the gate driver.

8. The display device of claim 1, wherein the second driver includes an emission driver which provides an emission control signal to the pixel circuits,
wherein the first connection line includes a first emission connection line connected to the emission driver,
wherein the second connection line includes a second emission connection line connected to the first emission connection line, and
wherein the signal line includes an emission signal line which is connected to the second emission connection line and transmits the emission control signal provided from the emission driver.

9. The display device of claim 1, further comprising:
a constant voltage line providing a constant voltage to the pixel circuits,
wherein the constant voltage line includes a first constant voltage line connected to the second driver and extending in the first direction, and a second constant voltage line connected to the first constant voltage line and extending in the second direction, and
wherein the first constant voltage line and the second constant voltage line are connected in the display area at a third contact point.

10. The display device of claim 9, wherein the third contact point overlaps each of the pixel circuits in a plan view.

11. The display device of claim 9, wherein the third contact point is positioned in the separation space between the adjacent pixel circuit groups.

12. The display device of claim 1, wherein the non-display area includes:
a first driver area positioned on the one side of the display area and where the first driver is disposed;
a second driver area positioned on the other side of the display area and where the second driver is disposed; and
bending areas respectively positioned between the display area and the first driver area and between the display area and the second driver area in a plan view, and
wherein the substrate is bendable about a reference axis parallel to the second direction in the bending areas.

13. The display device of claim 1, wherein the second connection line includes at least one selected from a group consisting of aluminum, copper, silver, molybdenum, and titanium.

14. A display device comprising:
a substrate including a display area and a non-display area surrounding the display area;
pixel circuit groups disposed in a matrix form along a first direction and a second direction which intersects the first direction on the substrate in the display area, each of the pixel circuit groups including pixel circuits;
a first driver disposed on the substrate in the non-display area on one side of the display area and providing a data voltage to the pixel circuits;
a second driver disposed on the substrate in the non-display area on the one side of the display area and providing a driving signal to the pixel circuits;
a first connection line connected to the second driver and extending in the first direction;
a second connection line connected to the first connection line in a separation space between adjacent pixel circuit groups and extending in the second direction; and
a signal line connected to the second connection line and transmitting the driving signal provided from the second driver to the pixel circuits.

15. The display device of claim 14, wherein the second connection line and the signal line are connected in the non-display area at a first contact point,
wherein the second driver is positioned to be spaced apart from the display area in the first direction, and
wherein the first contact point is positioned to be spaced apart from the display area in the second direction.

16. The display device of claim 14, wherein the first connection line and the second connection line are connected in the display area at a second contact point, and
wherein the second contact point is positioned in a first separation space between the adjacent pixel circuit groups arranged along the first direction.

17. The display device of claim 14, wherein the first connection line and the second connection line are connected in the display area at a second contact point, and
Wherein the second contact point is positioned in a second separation space between the adjacent pixel circuit groups arranged along the second direction.

18. The display device of claim 14, wherein the second driver includes a gate driver which provides a gate signal to the pixel circuits,
wherein the first connection line includes a first gate connection line connected to the gate driver,
wherein the second connection line includes a second gate connection line connected to the first gate connection line, and
wherein the signal line includes a gate signal line which is connected to the second gate connection line and transmits the gate signal provided from the gate driver.

19. The display device of claim 14, wherein the second driver includes an emission driver which provides an emission control signal to the pixel circuits,
wherein the first connection line includes a first emission connection line connected to the emission driver,
wherein the second connection line includes a second emission connection line connected to the first emission connection line, and
wherein the signal line includes an emission signal line which is connected to the second emission connection line and transmits the emission control signal provided from the emission driver.

20. The display device of claim 14, wherein the non-display area includes:
a driver area positioned on the one side of the display area and where each of the first driver and the second driver is disposed; and
a bending area positioned between the display area and the driver area in a plan view, and
wherein the substrate is bendable about a reference axis parallel to the second direction in the bending area.
